(19) United States
(12) Patent Application Publication
(10) Pub. No.: US 2022/0190203 A1
(43) Pub. Date: Jun. 16, 2022

(54) DISPLAY DEVICE AND METHOD OF REPAIRING DISPLAY DEVICE

(71) Applicant: Samsung Display Co., LTD., Yongin-si (KR)

(72) Inventors: Seul Ki Kim, Yongin-si (KR); Tae Ha Jin, Yongin-si (KR); Seon Beom Ji, Yongin-si (KR); Dong Hwan Kim, Yongin-si (KR); Sang Hoon Lee, Yongin-si (KR)

(73) Assignee: Samsung Display Co., LTD., Yongin-si (KR)

(21) Appl. No.: 17/387,401

(22) Filed: Jul. 28, 2021

(30) Foreign Application Priority Data
Dec. 15, 2020 (KR) 10-2020-0175872

(51) Int. Cl. H01L 33/38; G09G 3/00; H01L 27/15; H01L 33/44; H01L 33/62

(52) U.S. Cl. CPC H01L 33/38; G09G 3/006; H01L 33/62; H01L 33/44; H01L 27/156

(57) ABSTRACT

A display device includes a first electrode and a second electrode which are disposed on a substrate and face each other. Light-emitting elements are disposed between the first electrode and the second electrode. Markings are formed on the first electrode in a first extending direction of the first electrode in a plan view.

### CROSS-REFERENCE TO RELATED APPLICATION(S)

This application claims priority to and benefits of Korean Patent Application No. 10-2020-0175872 under 35 U.S.C. § 119 filed on Dec. 15, 2020 in the Korean Intellectual Property Office, the entire contents of which are incorporated herein by reference.

### BACKGROUND

### 1. Technical Field

The disclosure relates to a display device and a method of repairing the display device.

### 2. Description of the Related Art

As interests in information displays and demands on using portable information media increase, research and commercialization on display devices are actively performed.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure is directed to providing a display device of which defects may be more accurately repaired, and a method of repairing the display device.

A display device according to an embodiment may include a first electrode and a second electrode which are disposed on a substrate and face each other; light-emitting elements disposed between the first electrode and the second electrode; and markings formed on the first electrode in a first extending direction of the first electrode in a plan view.

In an embodiment, each of the markings may be a substantially concave pattern or a substantially convex pattern on a surface of the first electrode.

In an embodiment, the markings may be spaced apart from each other at a same interval over an entire section corresponding to the light-emitting elements in the first extending direction of the first electrode.

In an embodiment, the same interval may be in a range of about 4 μm to about 10 μm.

In an embodiment, each of the markings may have a substantially circular planar shape or a substantially quadrangular planar shape.

In an embodiment, each of the markings may be adjacent to a first side of the first electrode in a second extending direction perpendicular to the first extending direction of the first electrode in a plan view, and the first side of the first electrode may face the second electrode.

In an embodiment, each of the markings may extend in a second extending direction perpendicular to the first extending direction of the first electrode in the plan view.

In an embodiment, the markings include markings that may have different lengths in the second extending direction.

In an embodiment, each of the markings may contact a second side of the first electrode in a second extending direction perpendicular to the first extending direction of the first electrode, and the second side of the first electrode may be opposite to a first side of the first electrode facing the second electrode.

In an embodiment, the markings may be formed in the second electrode in an extending direction of the second electrode.

In an embodiment, the first electrode and the second electrode may be disposed in a same layer.

A display device according to an embodiment may include an insulating layer disposed on a substrate; a first bank pattern and a second bank pattern which are disposed on the insulating layer and face each other; a first electrode disposed on the first bank pattern; a second electrode disposed on the second bank pattern; a first passivation layer disposed on the first electrode and the second electrode; and light-emitting elements disposed on the first passivation layer between the first electrode and the second electrode, wherein markings are formed in one of the insulating layer, the first bank pattern, the second bank pattern, and the first passivation layer, and the markings may correspond to a section in which the light-emitting elements may be disposed in a plan view.

In an embodiment, the markings may be formed in the second bank pattern.

In an embodiment, the markings may be formed in an area of the second bank pattern not overlapping the second electrode in a plan view.

In an embodiment, the markings may be formed in the first passivation layer.

In an embodiment, the display device may further include a transistor disposed between the substrate and the insulating layer and electrically connected to the first electrode, wherein the insulating layer may contact a source electrode and a drain electrode of the transistor, and the markings may be formed in the insulating layer.

A method of repairing a display device according to an embodiment may include applying driving voltages to a first electrode and a second electrode extending to face each other on a substrate; forming markings on the first electrode or on an insulating layer adjacent to the first electrode; generating coordinate information of a defect based on a heating state of light-emitting elements disposed between the first electrode and the second electrode; generating the coordinate information based on the markings; and removing the defect from the display device based on the coordinate information.

In an embodiment, the generating of the coordinate information may include generating an optical image of the display device through an imaging device; generating a heating image of the light-emitting elements; and generating a test image by combining the optical image and the heating image, wherein the markings may be displayed on the optical image.

In an embodiment, the generating of the coordinate information may further include determining that the defect has occurred at a point at which a temperature value deviates from a reference range in the test image; and determining information of markings adjacent to the defect as the coordinate information.

In an embodiment, the removing of the defect may include cutting a portion of a light-emitting element or the first electrode corresponding to the coordinate information through a laser device, and the coordinate information may be provided to the laser device, and the test image may not be provided to the laser device.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view illustrating a light-emitting element according to an embodiment.

FIG. 2 is a schematic cross-sectional view of the light-emitting element of FIG. 1.

FIG. 3 is a schematic plan view illustrating a display device according to an embodiment, and for example, illustrating a display device using the light-emitting element shown in FIGS. 1 and 2 as a light source.

FIG. 4 is a schematic diagram of an equivalent circuit illustrating an electrical connection relationship between components included in a pixel shown in FIG. 3 according to an embodiment.

FIG. 5 is a schematic plan view illustrating a pixel shown in FIG. 3.

FIG. 6 is an enlarged plan view of a second emission area of FIG. 5 according to an embodiment.

FIG. 7 is a schematic plan view illustrating electrodes included in a pixel of FIG. 6 according to an embodiment.

FIGS. 8A and 8B are schematic cross-sectional views taken along line II-II″ of FIG. 7 which illustrate an electrode according to an embodiment.

FIG. 9 is a schematic plan view illustrating electrodes and light-emitting elements included in a pixel of FIG. 6 according to an embodiment.

FIGS. 10, 11, 12, 13, 14, and 15 are schematic plan views illustrating electrodes included in a pixel of FIG. 6 according to various embodiments.

FIGS. 16A and 16B are schematic cross-sectional views taken along line I-I′ of FIG. 6 which illustrate a pixel according to an embodiment.

FIG. 17 is a schematic cross-sectional view taken along line I-I′ of FIG. 6 which illustrates a pixel according to an embodiment.

FIG. 18 is an enlarged schematic plan view illustrating a second emission area of FIG. 5 according to an embodiment.

FIG. 19A is a schematic plan view illustrating bank patterns included in a pixel of FIG. 18 according to an embodiment.

FIG. 19B is a schematic cross-sectional view taken along line III-III′ of FIG. 19A which illustrates a pixel.

FIG. 20A is a schematic plan view illustrating a first passivation layer included in a pixel of FIG. 18 according to an embodiment.

FIGS. 20B to 20D are schematic cross-sectional views taken along line IV-IV′ of FIG. 20A which illustrate pixels.

FIG. 21 is a flowchart illustrating a method of repairing a display device according to an embodiment.

FIG. 22 shows images for describing a process of generating coordinate information of a defect occurring in a display device.

### DETAILED DESCRIPTION OF THE EMBODIMENTS

While the disclosure includes various modifications and alternative embodiments, embodiments thereof will be described and illustrated by way of example in the accompanying drawings. However, it should be understood that there is no intention to limit the disclosure to the embodiments disclosed, and, on the contrary, the disclosure is intended to cover all modifications, equivalents, and alternatives falling within the spirit and scope of the disclosure.

Like numbers refer to like elements throughout the drawings. In the accompanying drawings, the sizes of structures may be exaggerated for clarity.

Although the terms “first,” “second,” etc. are used herein to describe various elements, these elements should not be limited by these terms. The terms are used only for the purpose of distinguishing one element from another. For example, without departing from the scope of the disclosure, a first element could be termed a second element, and similarly a second element could be also termed a first element. A single form of expression is meant to include multiple elements unless otherwise stated.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

It will be understood that the terms “comprises” and/or “comprising,” or “includes” and/or “including,” “has,” “have,” and/or “having,” and variations thereof when used in this specification, specify the presence of stated features, integers, steps, operations, elements, components, and/or combinations thereof but do not preclude the presence or addition of one or more other features, integers, steps, operations, elements, components, and/or combinations thereof.

In addition, when a layer, a film, an area, or a plate is referred to as being “on” or “under” another layer, another film, another area, or another plate, it can be “directly” or “indirectly” on the other layer, film, area, plate, or one or more intervening layers may also be present. Further, in the disclosure, when a part of a layer, a film, an area, a plate, and the like is formed on another part, a direction, in which the part is formed, is not limited only to an up direction, and includes a lateral direction or a down direction. On the contrary, it will be understood that when an element such as a layer, film, area, or plate is referred to as being “beneath” another element, it can be directly beneath the other element or intervening elements may also be present.

In the application, when it is described that an element (such as a first element) is “operatively or communicatively coupled with/to” or “connected” to another element (such as a second element), the element can be directly connected to the other element or can be connected to the other element through another element (e.g., a third element). On the contrary, when it is described that an element (e.g., a first element) is “directly connected” or “directly coupled” to another element (e.g., a second element), it means that there is no intermediate element (e.g., a third element) between the element and the other element.

Hereinafter, embodiments of the disclosure and other subject matters necessary for those skilled in the art to understand the contents of the disclosure will be described in detail with reference to the accompanying drawings. In the following description, the singular forms “a,” “an,” and “the” are intended to include the plural forms as well, unless the context clearly indicates otherwise.

The phrase “in a plan view” means viewing the object from the top, and the phrase “in a schematic cross-sectional view” means viewing a cross-section of which the object is vertically cut from the side.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

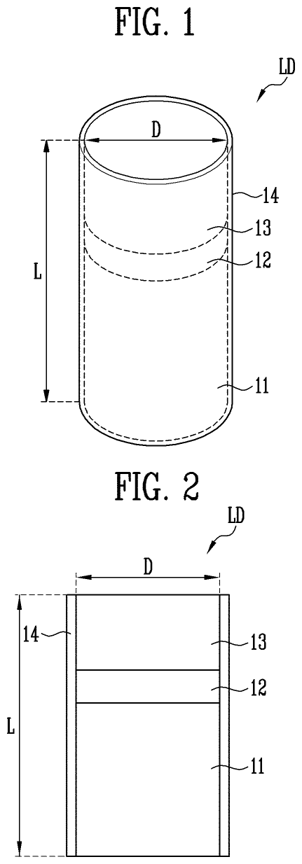

FIG. 1 is a schematic perspective view illustrating a light-emitting element according to an embodiment, and FIG. 2 is a schematic cross-sectional view of the light-emitting element of FIG. 1.

In an embodiment, the type and/or shape of the light-emitting element is not limited to that of the embodiment shown in FIGS. 1 and 2.

Referring to FIGS. 1 and 2, a light-emitting element LD may include a first semiconductor layer 11, a second semiconductor layer 13, and an active layer 12 interposed between the first semiconductor layer 11 and the second semiconductor layer 13. As an example, the light-emitting element LD may provide a light-emitting stack in which the first semiconductor layer 11, the active layer 12, and the second semiconductor layer 13 may be sequentially stacked each other.

The light-emitting element LD may be provided in a shape extending in a direction. In case that it is assumed that an extending direction of the light-emitting element LD is a length (L) direction, the light-emitting element LD may have an end portion (or a lower end portion) and another end portion (or an upper end portion) in the extending direction. One of the first and second semiconductor layers 11 and 13 may be positioned at the end portion (the lower end portion) of the light-emitting element LD, and the other may be positioned at the other end portion of the light-emitting element LD. As an example, the first semiconductor layer 11 may be positioned at the end portion (or the lower end portion) of the light-emitting element LD, and the second semiconductor layer 13 may be positioned at the other end portion (or the upper end portion) of the light-emitting element LD.

The light-emitting element LD may be provided in various shapes. As an example, the light-emitting element LD may have a substantially rod-like shape, a substantially bar-like shape, or a substantially column-like shape which is long in the length (L) direction (for example, having an aspect ratio greater than one). In an embodiment, the length L of the light-emitting element LD in the length (L) direction may be greater than a diameter D (or the width of a cross section thereof) thereof. However, the disclosure is not limited thereto, and in embodiments, the light-emitting element LD may have a substantially rod-like shape, a substantially bar-like shape, or a substantially column-like shape which is short in the length (L) direction (for example, having an aspect ratio smaller than one). The light-emitting element LD may have a substantially rod-like shape, a substantially bar-like shape, or a substantially column-like shape in which the length L is identical to the diameter D. The light-emitting element LD may include, for example, a light-emitting diode (LED) manufactured in a small size to have the diameter D and/or the length L to a degree of the nanoscale to the microscale.

In case that the light-emitting element LD is long in the length (L) direction (for example, having an aspect ratio greater than one), the diameter D of the light-emitting element LD may be in a range of about 0.5 μm to about 6 μm, and the length L thereof may be in a range of about 1 μm to about 10 μm. However, the diameter D and the length L of the light-emitting element LD are not limited thereto, and the size of the light-emitting element LD may be changed such that the light-emitting element LD meets requirements (or design conditions) of a lighting device or a self-luminous display device in which the light-emitting element LD is used.

As an example, the first semiconductor layer 11 may include at least one n-type semiconductor layer. For example, the first semiconductor layer 11 may be an n-type semiconductor layer which may include a semiconductor material selected from InAlGaN, GaN, AlGaN, InGaN, AlN, and InN and is doped with a first conductivity-type dopant (or an n-type dopant) such as silicon (Si), germanium (Ge), or tin (Sn). However, a material constituting the first semiconductor layer 11 is not limited thereto, and the first semiconductor layer 11 may be made of various materials. In an embodiment, the first semiconductor layer 11 may include a gallium nitride (GaN) semiconductor material doped with the first conductivity-type dopant (or the n-type dopant). The first semiconductor layer 11 may include an upper surface contacting the active layer 12 and a lower surface exposed to the outside in the length (L) direction of the light-emitting element device LD. The lower surface of the first semiconductor layer 11 may be the end portion (or the lower end portion) of the light-emitting element LD.

The active layer 12 may be disposed on the first semiconductor layer 11 and may have a single or multi-quantum well structure. As an example, in case that the active layer 12 has a multi-quantum well structure, a barrier layer (not shown), a strain reinforcing layer, and a well layer may be repeatedly and periodically stacked each other as a unit in the active layer 12. The strain reinforcing layer may have a smaller lattice constant than that of the barrier layer to further reinforce strain, for example, compression stress to be applied to the well layer. However, the structure of the active layer 12 is not limited to that of the above-described embodiment.

The active layer 12 may emit light having a wavelength of about 400 nm to about 900 nm and may have a double-hetero structure. In an embodiment, a clad layer (not shown) doped with a conductive dopant may be formed on an upper and/or lower portion of the active layer 12 in the length (L) direction of the light-emitting element LD. As an example, the clad layer may be formed as an AlGaN layer or an InAlGaN layer. According to embodiments, a material such as AlGaN or InAlGaN may be used to form the active layer 12, and in addition, various materials may constitute the active layer 12. The active layer 12 may have a first surface contacting the first semiconductor layer 11 and a second surface contacting the second semiconductor layer 13.

In case that an electric field having a voltage or more is applied to both end portions of the light-emitting element LD, electrons-hole pairs combine, and thus, the light-emitting elements LD emits light. Light emission of the light-emitting element LD may be controlled using such a principle, and the light-emitting element LD may be used as a light source (or a light-emitting source) of various light-emitting devices including pixels of a display device.

The second semiconductor layer 13 may be disposed on the second surface of the active layer 12 and may include a semiconductor layer which is a different type from the first semiconductor layer 11. As an example, the second semiconductor layer 13 may include at least one p-type semiconductor layer. For example, the second semiconductor layer 13 may include a p-type semiconductor layer which may include at least one semiconductor material selected from InAlGaN, GaN, AlGaN, InGaN, AlN, and InN and is doped with a second conductivity-type dopant (or a p-type dopant) such as magnesium (Mg). However, a material constituting the second semiconductor layer 13 is not limited thereto, and the second semiconductor layer 13 may be made of various materials. In an embodiment, the second semiconductor layer 13 may include a gallium nitride (GaN) semiconductor material doped with the second conductivity-type dopant (or the p-type dopant). The second semiconductor layer 13 may have a lower surface contacting the active layer 12 and an upper surface exposed to the outside in the length (L) direction of the light-emitting element LD. Here, the upper surface of the second semiconductor layer 13 may be the other end portion (or the upper end portion) of the light-emitting element LD.

In an embodiment, the first semiconductor layer 11 and the second semiconductor layer 13 may have different thicknesses in the length (L) direction of the light-emitting element LD. As an example, the first semiconductor layer 11 may have a thickness that is relatively greater than that of the second semiconductor layer 13 in the length (L) direction of the light-emitting element LD. Therefore, the active layer 12 of the light-emitting element LD may be positioned closer to the upper surface of the second semiconductor layer 13 than to the lower surface of the first semiconductor layer 11.

Each of the first semiconductor layer 11 and the second semiconductor layer 13 are illustrated as being formed as a layer, but the disclosure is not limited thereto. In an embodiment, each of the first semiconductor layer 11 and the second semiconductor layer 13 may further include one or more layers, for example, a clad layer and/or a tensile strain barrier reducing (TSBR) layer according to a material of the active layer 12. The TSBR layer may be a strain reducing layer disposed between semiconductor layers having different lattice structures to serve as a buffer for reducing a difference in lattice constant. The TSBR layer may be formed as a p-type semiconductor layer including p-GaInP, p-AlInP, or p-AlGaInP, but the disclosure is not limited thereto.

According to embodiments, in addition to the first semiconductor layer 11, the active layer 12, and the second semiconductor layer 13 described above, the light-emitting element LD may further include an additional electrode (not shown, hereinafter referred to as “a first additional electrode”) disposed on the second semiconductor layer 13. According to an embodiment, the light-emitting element LD may further include another additional electrode (not shown, hereinafter referred to as “a second additional electrode”) disposed at the end of the first semiconductor layer 11.

Each of the first and second additional electrodes may be an ohmic contact electrode, but the disclosure is not limited thereto. According to embodiments, the first and second additional electrodes may be Schottky contact electrodes. The first and second additional electrodes may include a conductive material. For example, the first and second additional electrodes may include one selected from chromium (Cr), titanium (Ti), aluminum (Al), gold (Au), nickel (Ni), and an opaque metal including an oxide or alloy thereof alone or in combination, but the disclosure is not limited thereto. According to embodiments, the first and second additional electrodes may include a transparent conductive oxide such as indium tin oxide (ITO), indium zinc oxide (IZO), zinc oxide (ZnO), indium gallium zinc oxide (IGZO), or indium tin zinc oxide (ITZO).

Materials included in the first and second additional electrodes may be the same or different. The first and second additional electrodes may be substantially transparent or semi-transparent. Therefore, light generated by the light-emitting element LD may be emitted to the outside of the light-emitting element LD by passing through the first and second additional electrodes. According to embodiments, in case that light generated by the light-emitting element LD does not pass through the first and second additional electrodes and is emitted to the outside of the light-emitting element LD through an area excluding both the end portions of the light-emitting-element LD, the first and second additional electrodes may include an opaque metal.

In an embodiment, the light-emitting element LD may further include an insulating film 14. However, according to embodiments, the insulating film 14 may be omitted and may cover or overlap only some or a number of the first semiconductor layer 11, the active layer 12, and the second semiconductor layer 13.

The insulating film 14 may prevent an electrical short circuit that may occur in case that the active layer 12 contacts conductive materials other than the first and second semiconductor layers 11 and 13. The insulating film 14 may minimize surface defects in the light-emitting element LD, thereby improving the life and emission efficiency of the light-emitting element LD. Furthermore, in case that light-emitting elements LD are closely disposed, the insulating film 14 may prevent an undesired short circuit that may occur between the light-emitting elements LD. If the active layer 12 may be prevented from being short-circuited with an external conductive material, the disclosure is not limited to whether the insulating film 14 is provided.

The insulating film 14 may entirely surround an outer peripheral surface of the light-emitting stack including the first semiconductor layer 11, the active layer 12, and the second semiconductor layer 13.

In the above-described embodiment, it has been described that the insulating film 14 entirely surround an outer peripheral surface of each of the first semiconductor layer 11, the active layer 12, and the second semiconductor layer 13, but the disclosure is limited thereto. According to embodiments, in case that the light-emitting element LD may include the first additional electrode, the insulating film 14 may entirely surround an outer peripheral surface of each of the first semiconductor layer 11, the active layer 12, the second semiconductor layer 13, and the first additional electrode. According to an embodiment, the insulating film 14 may not entirely surround the outer peripheral surface of the first additional electrode or may surround only a portion of the outer peripheral surface of the first additional electrode and may not surround the rest of the outer peripheral surface of the first additional electrode. According to embodiments, in case that the first additional electrode is disposed at the other end portion (or the upper end portion) of the light-emitting element LD, and the second additional electrode is disposed at the end portion (or the lower end portion) of the light-emitting element LD, it is possible to expose an area of each of the first and second additional electrodes.

The insulating film 14 may include a transparent insulating material. For example, the insulating film 14 may include at least one insulating material selected from the group consisting of silicon oxide (SiOₓ), silicon nitride (SiNₓ), silicon oxynitride (SiOₓN_{y}), aluminum oxide (AlOₓ), titanium oxide (TiOₓ), hafnium oxide (HfOₓ), titanium strontium oxide (SrTiOₓ), cobalt oxide (CoxO_{y}), magnesium oxide (MgO), zinc oxide (ZnO), ruthenium oxide (RuOₓ), nickel oxide (NiO), tungsten oxide (WOₓ), tantalum oxide (TaOₓ), gadolinium oxide (GdOₓ), zirconium oxide (ZrOₓ), gallium oxide (GaOₓ), vanadium oxide (VₓO_{y}), ZnO:Al, ZnO:B, InₓO_{y}:H, niobium oxide (NbₓO_{y}), magnesium fluoride (MgFₓ), aluminum fluoride (AlFₓ), an alucone polymer film, titanium nitride (TiN), tantalum nitride (TaN), aluminum nitride (AlNₓ), gallium nitride (GaN), tungsten nitride (WN), hafnium nitride (HfN), niobium nitride (NbN), gadolinium nitride (GdN), zirconium nitride (ZrN), and vanadium nitride (VN). However, the disclosure is not limited thereto, and various materials having insulating properties may be used as a material of the insulating film 14.

The insulating film 14 may be formed as a single film or multiple films including at least two films. As an example, in case that the insulating film 14 is formed as a double film including a first layer and a second layer which may be sequentially stacked each other, the first layer and the second layer may be made of different substances (or materials) and may be formed by different (or separate) processes. According to embodiments, the first layer and the second layer may be made of a same material or may be formed by consecutive processes.

According to embodiments, the light-emitting element LD may be provided as a light-emitting pattern having a core-shell structure. The first semiconductor layer 11 may be positioned at a core, for example, a middle (or center) of the light-emitting element LD, and the active layer 12 may be provided or formed or disposed to surround the outer peripheral surface of the first semiconductor layer 11. The second semiconductor layer 13 may be provided or formed or disposed to surround the active layer 12. The light-emitting element LD may further include an additional electrode (not shown) surrounding at least one side or a side of the second semiconductor layer 13. According to embodiments, the light-emitting element LD may further include the insulating film 14 which is provided or disposed on an outer peripheral surface of the light-emitting pattern having a core-shell structure and may include a transparent insulating material. The light-emitting element LD provided as the light-emitting pattern having a core-shell structure may be manufactured by a growth method.

The light-emitting element LD may be used as a light-emitting source (or a light source) of various display devices. The light-emitting element LD may be manufactured by a surface treatment process. For example, in case that light-emitting elements LD are mixed in a flowable solution (or solvent) and supplied to each pixel area (for example, an emission area of each pixel or an emission area of each subpixel), the light-emitting elements LD may be surface-treated so as to be uniformly sprayed without being non-uniformly aggregated in the solution.

A light-emitting unit (or a light-emitting device) including the light-emitting element LD may be used in various types of electronic devices, such as display devices, which require a light source. For example, in case that the light-emitting elements LD are disposed in the pixel area of each pixel of a display panel, the light-emitting elements LD may be used as light sources of each pixel. However, the field of application of the light-emitting element LD is not limited to that of the above-described example. For example, the light-emitting element LD may be used in other types of electronic devices, such as lighting devices, which require a light source.

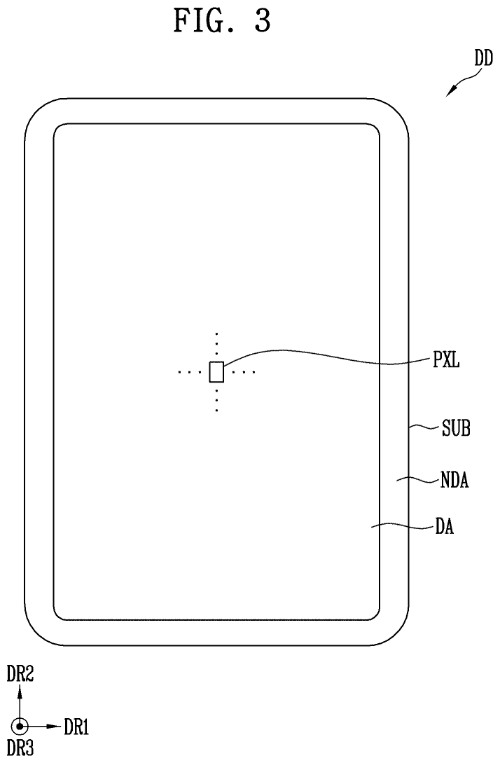

FIG. 3 is a schematic plan view illustrating a display device according to an embodiment, for example, illustrating a display device using the light-emitting element shown in FIGS. 1 and 2 as a light source.

FIG. 3 illustrates, for convenience, a schematic structure of a display device DD, focusing on a display area DA in which an image is displayed.

Referring to FIGS. 1, 2, and 3, the display device DD may include a substrate SUB (or a base layer), pixels PXL which are provided or disposed on the substrate SUB and each include one or more light-emitting elements LD, a driver which is provided or disposed on the substrate SUB and drives the pixels PXL, and a line portion which electrically connects the pixels PXL to the driver.

In case that the display device DD is an electronic device, in which a display surface is used as at least one surface or a surface thereof, such as a smartphone, a television, a tablet personal computer (PC), a mobile phone, a display phone, an e-book reader, a desktop PC, a laptop PC, a netbook PC, a workstation, a server, a personal digital assistant (PDA), a portable multimedia player (PMP), an MP3 player, a medical device, a camera, or a wearable device, the disclosure may be applied to the display device DD.

The display device DD may be classified into a passive matrix type display device and an active matrix type display device according to a method of driving the light-emitting element LD. As an example, in case that the display device DD is provided as an active matrix type display device, each of the pixels PXL may include a driving transistor which controls an amount of a current supplied to the light-emitting element LD, a switching transistor which transmits a data signal to the driving transistor, and the like within the spirit and the scope of the disclosure.

The display device DD may be provided in various shapes, and for example, may be provided in a substantially rectangular plate shape having two pairs of sides parallel to each other, but the disclosure is not limited thereto. In case that the display device DD is provided in a substantially rectangular plate shape, one of two pairs of sides thereof may be longer than the other. For convenience, a case is illustrated in which the display device DD has a substantially rectangular shape having a pair of long sides and a pair of short sides. An extending direction of the long side may be expressed as a second direction DR2, an extending direction of the short side may be expressed as a first direction DR1, and a direction perpendicular to the extending directions of the long side and the short side may be expressed as a third direction DR3. In the display device DD provided in the substantially rectangular plate shape, a corner at which a long side contacts (or meets) a short side may have a substantially round shape.

The substrate SUB may include the display area DA and a non-display area NDA.

The display area DA may be an area in which the pixels PXL displaying an image are provided. The non-display area NDA may be an area in which the driver for driving the pixels PXL and a portion of the line portion for electrically connecting the pixels PXL to the driver are provided. For convenience, FIG. 3 illustrates only a pixel PXL, but the pixels PXL may be substantially disposed in the display area DA of the substrate SUB.

The non-display area NDA may be provided or disposed on at least one side or a side of the display area DA. The non-display area NDA may surround or may be adjacent to a periphery (or edge) of the display area DA. The line portion electrically connected to the pixels PXL and the driver electrically connected to the line portion and for driving the pixels PXL may be provided or disposed in the non-display area NDA.

The line portion may electrically connect the driver and the pixels PXL. The line portion may provide a signal to each pixel PXL and may be a fan-out line electrically connected to signal lines, for example, a scan line, a data line, and an emission control line. The line portion may be a fan-out line electrically connected to signal lines electrically connected to each pixel PXL, for example, a control line and a sensing line in order to compensate for changes in electrical characteristics of each pixel PXL in real time.

The substrate SUB may include a transparent insulating material to transmit light. The substrate SUB may be a rigid or flexible substrate.

An area of the substrate SUB may be provided as the display area DA, and thus, the pixels PXL may be disposed therein. The remaining area of the substrate SUB may be provided as the non-display area NDA. As an example, the substrate SUB may include the display area DA including pixel areas in which the pixels PXL are disposed, and may include the non-display area NDA disposed around (or adjacent to) the display area DA.

The pixels PXL may each be provided or disposed in the display area DA of the substrate SUB. In an embodiment, the pixels PXL may be arranged or disposed in the display area DA in a stripe arrangement structure or a PenTile® arrangement structure, but the disclosure is not limited thereto.

Each pixel PXL may include one or more light-emitting elements LD driven by a corresponding scan signal and a corresponding data signal. The light-emitting element LD may have a small size to a degree of the nanoscale to the microscale and may be parallel with the light-emitting elements disposed adjacent thereto, but the disclosure is not limited thereto. The light-emitting element LD may constitute a light source of each pixel PXL.

Each pixel PXL may include at least one light source, for example, the light-emitting element LD shown in FIGS. 1 and 2 driven by signals (for example, a scan signal and a data signal) and/or power sources (for example, a first driving power source and a second driving power source). However, in embodiments, the type of the light-emitting element LD usable as the light source of each pixel PXL is not limited thereto.

The driver may provide a signal and power to each pixel PXL through the line portion to control driving of the pixel PXL. The driver may include a scan driver, an emission driver, a data driver, and a timing controller.

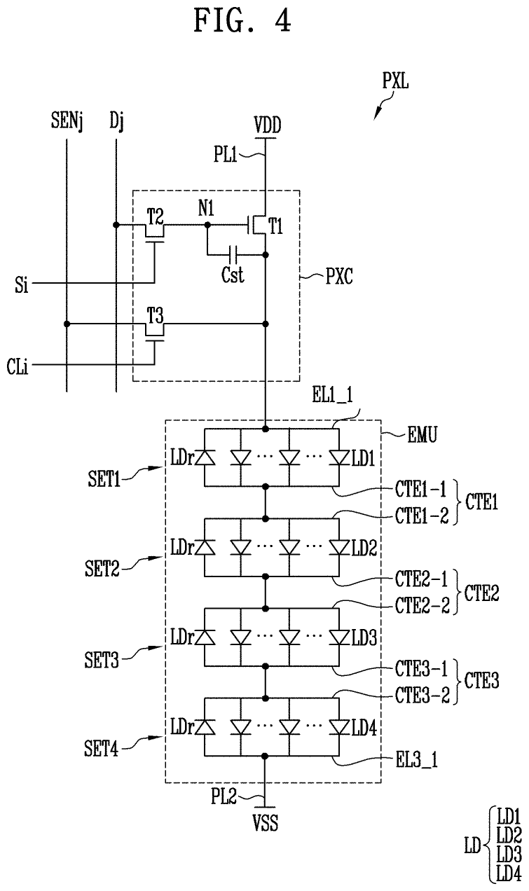

FIG. 4 is a schematic diagram of an equivalent circuit illustrating an electrical connection relationship between components included in a pixel shown in FIG. 3 according to an embodiment.

For example, FIG. 4 illustrates an electrical connection relationship between components included in pixels PXL that can be used in an active type display device according to an embodiment. However, the types of the components included in the pixel PXL to which the embodiment of the disclosure is applicable are not limited thereto.

As illustrated in FIG. 4, not only the components included in each of the pixels PXL shown in FIG. 3, but also an area in which the components are provided, may be referred to as the pixel PXL.

Referring to FIGS. 1 to 4, a pixel PXL may include a light-emitting unit EMU which generates light having luminance corresponding to a data signal. The pixel PXL may further include a pixel circuit PXC for driving the light-emitting unit EMU.

According to embodiments, the light-emitting unit EMU may include light-emitting elements LD electrically connected in parallel between a first power line PL1 to which a voltage of a first driving power source VDD is applied and a second power line PL2 to which a voltage of a second driving power source VSS is applied. For example, the light-emitting unit EMU may include a first-first electrode EL1_1 (or “a first alignment electrode”) electrically connected to the first driving power source VDD through the pixel circuit PXC and the first power line PL1, a third-first electrode EL3_1 (or “a second alignment electrode”) electrically connected to the second driving power source VSS through the second power line PL2, and the light-emitting elements LD electrically connected in series and parallel between the first-first electrode EL1_1 and the third-first electrode EL3_1. In an embodiment, the first-first electrode EL1_1 may be an anode, and the third-first electrode EL3_1 may be a cathode.

Each of the light-emitting elements LD included in the light-emitting unit EMU may include an end portion electrically connected to the first driving power source VDD through the first-first electrode EL1_1 and another end portion electrically connected to the second driving power source VSS through the third-first electrode EL3_1. The first driving power source VDD and the second driving power source VSS may have different potentials. As an example, the first driving power source VDD may be set as a high-potential power source, and the second driving power source VSS may be set as a low-potential power source. A potential difference between the first driving power source VDD and the second driving power source VSS may be set to be greater than or equal to a threshold voltage of the light-emitting elements LD during an emission period of the pixel PXL.

The respective light-emitting elements LD may be electrically connected in parallel in a same direction (for example, a forward direction) between the first-first electrode EL1_1 and the third-first electrode EL3_1 to which voltages having different potentials are supplied. The light-emitting elements LD may constitute each effective light source. The effective light sources may constitute the light-emitting unit EMU of the pixel PXL.

The light-emitting elements LD of the light-emitting unit EMU may emit light having luminance corresponding to a driving current supplied through the corresponding pixel circuit PXC. For example, during each frame period, the pixel circuit PXC may supply a driving current, corresponding to a grayscale value of corresponding frame data, to the light-emitting unit EMU. The driving current supplied to the light-emitting unit EMU may flow in each of the light-emitting elements LD. Therefore, while each light-emitting element LD emits light at luminance corresponding to a current flowing therein, the light-emitting unit EMU may emit light at luminance corresponding to the driving current.

An embodiment is illustrated in which both end portions of the light-emitting elements LD are electrically connected in a same direction between the first driving power source VDD and the second driving power source VSS, but the disclosure is not limited thereto. According to embodiments, the light-emitting unit EMU may further include at least one ineffective light source, for example, a reverse light-emitting element LDr, in addition to the light-emitting-elements LD constituting the effective light sources. The reverse light-emitting element LDr may be electrically connected parallel with the light-emitting elements LD constituting the effective light sources between the first-first electrode EL1_1 and the third-first electrode EL3_1 and may be electrically connected between the first-first electrode EL1_1 and the third-first electrode EL3_1 in a direction opposite to that of the light-emitting elements LD. The reverse light-emitting element LDr may maintain an inactive state even in case that a driving voltage (for example, a forward driving voltage) is applied between the first-first electrode EL1_1 and the third-first electrode EL3_1, and thus, no current may not substantially flow in the reverse light-emitting element LDr.

The pixel circuit PXC may be electrically connected to a scan line Si and a data line Dj of the corresponding pixel PXL. As an example, in case that the pixel PXL is disposed in an i^{th} row and a j^{th} column of a display area DA (where i is an integer and j is an integer), the pixel circuit PXC of the pixel PXL may be electrically connected to an i^{th} scan line Si and a j^{th} data line Dj of the display area DA. The pixel circuit PXC may be electrically connected to an i^{th} control line CLi and a i^{th} sensing line SENj of the display area DA.

The pixel circuit PXC may include first, second, and third transistors T1, T2, and T3 and a storage capacitor Cst.

A first terminal (for example, a drain electrode) of the first transistor T1 (driving transistor) may be electrically connected to the first driving power source VDD, and a second terminal (for example, a source electrode) thereof may be electrically connected to the first-first electrode EL1_1 of each of the light-emitting elements LD. A gate electrode of the first transistor T1 may be electrically connected to a first node N1. The first transistor T1 may control an amount of a driving current supplied to the light-emitting elements LD in response to a voltage of the first node N1.

A first terminal of the second transistor T2 (a switching transistor) may be electrically connected to the j^{th} data line Dj, and a second terminal thereof may be electrically connected to the first node N1. A gate electrode of the second transistor T2 may be electrically connected to the i^{th} scan line Si. In case that a scan signal having a voltage, at which the second transistor T2 may be turned on, is supplied from the i^{th} scan line Si to the second transistor T2, the second transistor T2 may be turned on to electrically connect the j^{th} data line Dj and the first node N1. A data signal of a corresponding frame may be supplied to the j^{th} data line Dj, and thus, the data signal may be transmitted to the first node N1. The data signal transmitted to the first node N1 may be charged in the storage capacitor Cst.

The third transistor T3 may be electrically connected between the first transistor T1 and the j^{th} sensing line SENj. For example, a first terminal of the third transistor T3 may be electrically connected to the second terminal of the first transistor Ti electrically connected to the first-first electrode EL1_1, and a second terminal of the third transistor T3 may be electrically connected to the j^{th} sensing line SENj. A gate electrode of the third transistor T3 may be electrically connected to the i^{th} control line CLi. The third transistor T3 may be turned on in response to a control signal having a gate-on voltage supplied to the i^{th} control line CLi during a sensing period, thereby electrically connecting the j^{th} sensing line SENj and the first transistor T1.

The sensing period may be a period for extracting characteristic information (for example, a threshold voltage or the like of the first transistor T1) of each of the pixels PXL disposed in the display area DA.

The storage capacitor Cst may be formed between the first node N1 and the first-first electrode EL1_1. For example, an electrode of the storage capacitor Cst may be electrically connected to the first node N1, and another electrode thereof may be electrically connected to the first-first electrode EL1_1. The storage capacitor Cst may be charged with a voltage corresponding to a data signal supplied to the first node N1 and may maintain the charged voltage until a data signal of a subsequent frame is supplied.

Each light-emitting unit EMU may include at least one series stage including the light-emitting elements LD electrically connected to each other in parallel. For example, as shown in FIG. 4, the light-emitting unit EMU may also have a series-parallel combination structure.

The light-emitting unit EMU may include a first series stage SET1, a second series stage SET2, a third series stage SET3, and a fourth series stage SET4 which may be sequentially and electrically connected between the first driving power source VDD and the second driving power source VSS. The light-emitting unit EMU may include two electrodes EL1_1 and CTE1, CTE1 and CTE2, CTE2 and CTE3, or CTE3 and EL3_1 constituting an electrode pair of a corresponding series stage, and the light-emitting elements LD electrically connected in parallel in a same direction between the two electrodes EL1_1 and CTE1, CTE1 and CTE2, CTE2 and CTE3, or CTE3 and EL3_1.

The first series stage SET1 may include the first-first electrode EL1_1 and a first-first intermediate electrode CTE1_1 and may include one or more first light-emitting elements LD1 electrically connected between the first-first electrode EL1_1 and the first-first intermediate electrode CTE1_1. The first series stage SET1 may also include the reverse light-emitting element LDr electrically connected in a direction opposite to that of the first light-emitting element LD1 between the first-first electrode EL1_1 and the first-first intermediate electrode CTE1_1.

The second series stage SET2 may include a first-second intermediate electrode CTE1_2 and a second-first intermediate electrode CTE2_1 and may include one or more second light-emitting elements LD2 electrically connected between the first-second intermediate electrode CTE1_2 and the second-first intermediate electrode CTE2_1. The second series stage SET2 may also include the reverse light-emitting element LDr electrically connected in a direction opposite to that of the second light-emitting element LD2 between the first-second intermediate electrode CTE1_2 and the second-first intermediate electrode CTE2_1.

The first-first intermediate electrode CTE1_1 of the first series stage SET1 and the first-second intermediate electrode CTE1_2 of the second series stage SET2 may be integrally provided and electrically connected to each other. For example, the first-first intermediate electrode CTE1_1 and the first-second intermediate electrode CTE1_2 may constitute a first intermediate electrode CTE1 that electrically connects the consecutive first and second series stages SET1 and SET2. In case that the first-first intermediate electrode CTE1_1 is integrally provided, the first-first intermediate electrode CTE1_1 may be a different area of the first intermediate electrode CTE1.

The third series stage SET3 may include a second-second intermediate electrode CTE2_2 and a third-first intermediate electrode CTE3_1 and may include one or more third light-emitting elements LD3 electrically connected between the second-second intermediate electrode CTE2_2 and the third-first intermediate electrode CTE3_1. The third series stage SET3 may include the reverse light-emitting element LDr electrically connected in a direction opposite to that of the third light-emitting element LD3 between the second-second intermediate electrode CTE2_2 and the third-first intermediate electrode CTE31.

The second-first intermediate electrode CTE2_1 of the second series terminal SET2 and the second-second intermediate electrode CTE2_2 of the third series stage SET3 may be integrally provided and electrically connected to each other. For example, the second-first intermediate electrode CTE2_1 and the second-second intermediate electrode CTE2_2 may constitute a second intermediate electrode CTE2 that electrically connects the consecutive second and third series stages SET2 and SET3.

The fourth series stage SET4 may include a third-second intermediate electrode CTE3_2 and the third-first electrode EL3_1 and may include one or more fourth light-emitting elements LD4 electrically connected between the third-second intermediate electrode CTE3_2 and the third-first electrode EL3_1. The fourth series stage SET4 may include the reverse light-emitting element LDr electrically connected in a direction opposite to that of the fourth light-emitting element LD4 between the third-second intermediate electrode CTE3_2 and the third-first electrode EL3_1.

The third-first intermediate electrode CTE3_1 of the third series terminal SET3 and the third-second intermediate electrode CTE3_2 of the fourth series stage SET4 may be integrally provided and electrically connected to each other. For example, the third-first intermediate electrode CTE3_1 and the third-second intermediate electrode CTE3_2 may constitute a third intermediate electrode CTE3 that electrically connects the consecutive third and fourth series stages SET3 and SET4.

In the above-described embodiment, the first-first electrode EL1_1 of the first series stage SET1 may be an anode of the light-emitting unit EMU of each pixel PXL, and the third-first electrode EL3_1 of the fourth series stage SET4 may be a cathode of the light-emitting unit EMU.

FIG. 4 illustrates an embodiment in which all of the first to third transistors T1 to T3 are N-type transistors, but the disclosure is not limited thereto. For example, at least one of the first to third transistors T1 to T3 may be changed to a P-type transistor. FIG. 4 illustrates an embodiment in which the light-emitting unit EMU is electrically connected between the pixel circuit PXC and the second driving power source VSS, but the light-emitting unit EMU may be electrically connected between the first driving power source VDD and the pixel circuit PXC.

The structure of the pixel circuit PXC may be variously changed. As an example, the pixel circuit PXC may further additionally include other circuit elements such as a transistor element for initializing the first node N1 and/or a transistor element for controlling emission times of the light-emitting elements LD, and a boosting capacitor for boosting a voltage of the first node N1.

The structure of the pixel PXL applicable to the disclosure is not limited to that of the embodiment shown in FIG. 4, and the pixel PXL may have various structures. For example, each pixel PXL may be provided or disposed inside of a passive-type light-emitting display device. The pixel circuit PXC may be omitted, and both end portions of the light-emitting elements LD included in the light-emitting unit EMU may be electrically connected to or directly electrically connected to the i^{th} scan line Si, the j^{th} data line Dj, the first power line PL1 to which the first driving power source VDD is electrically connected, the second power line PL2 to which the second driving power source VSS is electrically connected, and/or a control line.

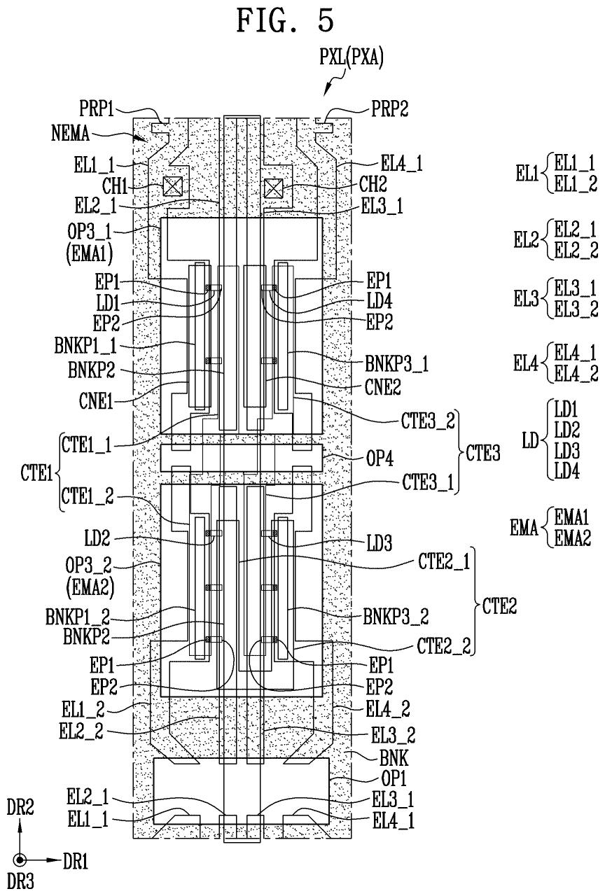

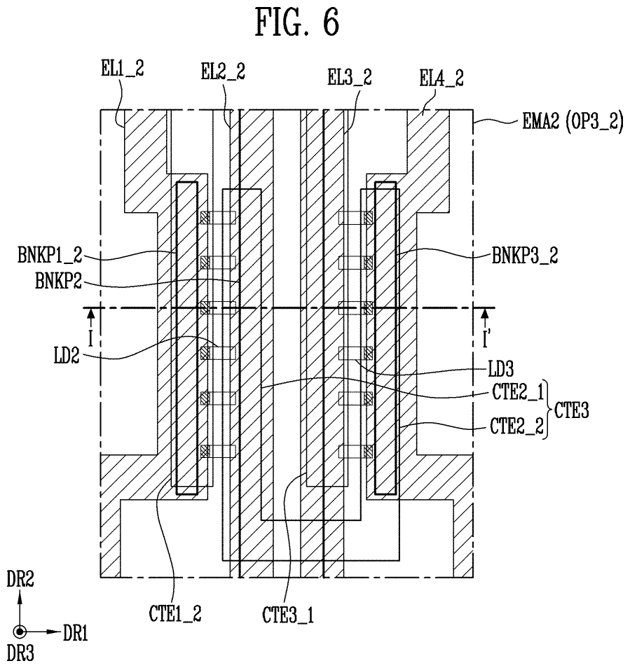

FIG. 5 is a schematic plan view illustrating a pixel shown in FIG. 3. FIG. 6 is a schematic enlarged plan view of a second emission area of FIG. 5 according to an embodiment. For convenience, transistors T electrically connected to light-emitting elements LD and signal lines electrically connected to the transistors T are omitted from FIGS. 5 and 6.

In an embodiment, for convenience of description, a lateral direction (or a horizontal direction) in a plan view is indicated by a first direction DR1, and a longitudinal direction (or a vertical direction) in a plan view is indicated by a second direction DR2. A thickness direction of the substrate SUB in a cross-sectional view is indicated by a third direction DR3. The first to third directions DR1, DR2, and DR3 may refer to directions indicated by the first to third directions DR1, DR2, and DR3, respectively.

In an embodiment, the term “connection” between two components may mean that both electrical connection and physical connection are used inclusively.

In an embodiment, “formed and/or provided in a same layer” may mean “formed by a same process,” and “formed and/or provided in a different layer” may mean “formed by different processes.”

Referring to FIGS. 3 and 5, each pixel PXL may be provided and/or formed or disposed in a pixel area PXA. The pixel area PXA may include an emission area EMA and a non-emission area NEMA. In an embodiment, the emission area EMA may include a first emission area EMA1 and a second emission area EMA2. In disclosure, the emission area EMA may be defined as an area in which the light-emitting elements LD are surrounded by a bank BNK.

According to embodiments, each pixel PXL may include the bank BNK positioned in the non-emission area NEMA.

The bank BNK may be a structure defining (or partitioning) the pixel area PXA or the emission area EMA of each of the corresponding pixel PXL and adjacent pixels PXL and may be, for example, a pixel definition film. As an example, the pixel area PXA may be partitioned to include an emission area EMA by the bank BNK. However, the disclosure is not limited thereto, and according to embodiments, the pixel area PXA may be partitioned to include at least two emission areas by the bank BNK.

In an embodiment, in a process of supplying (introducing) the light-emitting elements LD to each pixel PXL, the bank BNK may be a pixel definition film or a dam structure defining each emission area EMA to which the light-emitting elements LD are to be supplied. As an example, the emission area EMA of each pixel PXL may be partitioned by the bank BNK, and thus, a mixed solution (for example, ink) including a desired amount and/or type of light-emitting elements LD may be supplied (or introduced) to the emission area EMA.

The bank BNK may include at least one light blocking material and/or at least one reflective material to prevent light leakage defects that light (or a ray) leaks between each pixel PXL and adjacent pixels PXL. According to embodiments, the bank BNK may include a transparent material (or substance). The transparent material may include, for example, a polyamide-based resin, a polyimide-based rein, or the like, but the disclosure is not limited thereto. According to an embodiment, a reflective material layer may be separately provided and/or formed or disposed on the bank BNK in order to further improve efficiency of light emitted from each pixel PXL.

The bank BNK may include one or more opening areas exposing components positioned under or below the bank BNK in the pixel area PXA of the corresponding pixel PXL. As an example, the bank BNK may include a first opening area OP1 and a third-first opening area OP3_1, a third-second opening area OP3_2, and a fourth opening area OP4 that expose the components positioned under or below the bank BNK in the pixel area PXA of the corresponding pixel PXL. In an embodiment, the first emission area EMA1 of each pixel PXL and the third-first opening area OP3_1 of the bank BNK may correspond to each other, and the second emission EMA2 of the corresponding pixel PXL and the third-second opening area OP3_2 of the bank BNK may correspond to each other.

Each of the pixels PXL may include a first electrode EL1, a second electrode EL2, a third electrode EL3, and a fourth electrode EL4 which are arranged or disposed in the first direction DR1 and spaced apart from each other.

The first electrode EL1, the second electrode EL2, the third electrode EL3, and the fourth electrode EL4 may be sequentially arranged or disposed in the first direction DR1. The first electrode EL1, the second electrode EL2, the third electrode EL3, and the fourth electrode EL4 may extend, for example, in the second direction DR2 that is different from and intersects the first direction DR1.

Each of the first to fourth electrodes EL1 to EL4 may include two electrodes positioned in a same column in the pixel area PXA of each pixel PXL. As an example, the first electrode EL1 may include a first-first electrode EL1_1 and a first-second electrode EL1_2 that are positioned in a same column and are spaced apart from and face each other, the second electrode EL2 may include a second-first electrode EL2_1 and a second-second electrode EL2_2 that are positioned in a same column and are spaced apart from and face each other, the third electrode EL3 may include a third-first electrode EL3_1 and a third-second electrode EL3_2 that are positioned in a same column and are spaced apart from and face each other, and the fourth electrode EL4 may include a fourth-first electrode EL4_1 and a fourth-second electrode EL4_2 that are positioned in a same column and are spaced apart from and face each other.

The firs-first electrode EL1_1, the second-first electrode EL2_1, the third-first electrode EL3_1, and the fourth-first electrode EL4_1 may be positioned in the first emission area EMA1 of the corresponding pixel PXL. The first-second electrode EL1_2, the second-second electrode EL2_2, the third-second electrode EL3_2, and the fourth-second electrode EL4_2 may be positioned in the second emission area EMA2 of the corresponding pixel PXL.

An end portion of each of the first-first electrode EL1_1, the second-first electrode EL2_1, the third-first electrode EL3_1, and the fourth-first electrode EL4_1 and an end portion of each of the first-second electrode EL1_2, the second-second electrode EL2_2, the third-second electrode EL3_2, and the fourth-second electrode EL4_2 may be positioned in the first opening area OP1 of the bank BNK. After the light-emitting elements LD are aligned, the first to fourth electrodes EL1 to EL4 may be separated from different electrodes (for example, electrodes of adjacent pixels PXL adjacent to each other in the second direction DR2) in the first opening area OP1.

Another end portion of each of the first-first electrode EL1_1, the second-first electrode EL2_1, the third-first electrode EL3_1, and the fourth-first electrode EL4_1 and another end portion of each of the first-second electrode EL1_2, the second-second electrode EL2_2, the third-second electrode EL3_2, and the fourth-second electrode EL4_2 may be positioned in the fourth opening area OP4 of the bank BNK. After the light-emitting elements LD are aligned, each of the first-first electrode EL1_1, the second-first electrode EL2_1, the third-first electrode EL3_1, and the fourth-first electrode EL4_1 and each of the first-second electrode EL1_2, the second-second electrode EL2_2, the third-second electrode EL3_2, and the fourth-second electrode EL4_2 may be separated from each other in the fourth opening area OP4 so that the light-emitting unit EMU (see FIG. 4) of each pixel PXL may include four series stages. In an embodiment, the fourth opening area OP4 of the bank BNK may correspond to an area center of the emission area EMA of the corresponding pixel PXL.

The first to fourth electrodes EL1 to EL4 may be made of a material having reflectance to allow light, emitted from each of the light-emitting elements LD, to travel in an image display direction (for example, a front direction) of a display device DD. The first to fourth electrodes EL1 to EL4 may be made of a conductive material having reflectance.

Since the first-first electrode EL1_1, the second-first electrode EL2_1, the third-first electrode EL3_1, and the fourth-first electrode EL4_1 are symmetrical with the first-second electrode EL1_2, the second-second electrode EL2_2, the third-second electrode EL3_2, and the fourth-second electrode EL4_2 based on the fourth opening area OP4 of the bank BNK, respectively, the first-second electrode EL1_2, the second-second electrode EL2_2, the third-second electrode EL3_2, and the fourth-second electrode EL4_2 will be described.

The first-second electrode EL1_2 may have a shape substantially curved toward the second-second electrode EL2_2 in the first direction DR1 in the second emission area EMA2. The substantially curved shape of the first-second electrode EL1_2 may maintain an interval between the first-second electrode EL1_2 and the second-second electrode EL2_2 in the second emission area EMA2. Likewise, the fourth-second electrode EL4_2 may have a shape substantially curved toward the third-second electrode EL3_2 in the first direction DR1 in the second emission area EMA2. The substantially curved shape of the fourth-second electrode EL4_2 may maintain an interval between the third-second electrode EL3_2 and the fourth-second electrode EL4_2. However, the shapes of the first-second electrode EL1_2 and the fourth-second electrode EL4_2 are not limited thereto. For example, the shapes and/or mutual arrangement relationship of the first-second electrode EL1_2, the second-second electrode EL2_2, the third-second electrode EL3_2, and the fourth-second electrode EL4_2 may be variously changed. For example, each of the first-second electrode EL1_2 and the fourth-second electrode EL4_2 may have no curved shape and may include a protrusion.

As shown in FIG. 5, the first-first electrode EL1_1 may include a first protruding pattern PRP1 protruding in the first direction DR1 in the non-emission area NEMA positioned around the first emission area EMA1. The first protruding pattern PRP1 may protrude in a direction toward a fourth electrode (not shown) of a pixel (not shown) immediately adjacent to the first electrode EL1 of the corresponding pixel PXL among the pixels PXL positioned in an identical pixel row to the corresponding pixel PXL. The first protruding pattern PRP1 may be formed by a process in which the first electrode EL1 is separated from the first electrodes EL1 of the adjacent pixels PXL in the second direction DR2 in an operation of manufacturing the display device DD.

Likewise, the fourth-first electrode EL4_1 may include a second protruding pattern PRP2 protruding in the first direction DR1 in the non-emission area NEMA positioned around the first emission area EMA1. The second protruding pattern PRP2 may protrude in a direction toward a first electrode (not shown) of a pixel (not shown) immediately adjacent to the fourth electrode EL4 of the corresponding pixel PXL among the pixels PXL positioned in an identical pixel row to the corresponding pixel PXL. The second protruding pattern PRP2 may be formed by a process in which the fourth electrode EL4 is separated from the fourth electrodes EL4 of the adjacent pixels PXL in an operation of manufacturing the display device DD.

In an embodiment, the first protruding pattern PRP1 and the second protruding pattern PRP2 may protrude in opposite directions. For example, a protruding direction of the first protruding pattern PRP1 may be different from that of the second protruding pattern PRP2. As an example, the first protruding pattern PRP1 may protrude to a side (for example, a left side) in the first direction DR1 in a plan view, and the second protruding pattern PRP2 may protrude to another side (for example, a right side) in the first direction DR1 in a plan view.

The first-first electrode EL1_1 may be electrically connected to the first transistor T1 described with reference to FIG. 4 through a first contact hole CH1, and the third-first electrode EL3_1 may be electrically connected to the second driving power source VSS (or the second power line PL2) described with reference to FIG. 4 through a second contact hole CH2. In an embodiment, the first-first electrode EL1_1 may be an anode of the light-emitting unit EMU (see FIG. 4) of each pixel PXL, and the third-first electrode EL3_1 may be a cathode of the light-emitting unit EMU of the corresponding pixel PXL.

Each of the first to fourth electrodes EL1 to EL4 may be used as an alignment electrode (or an alignment line) for aligning the light-emitting elements LD by receiving an alignment signal from a power pad portion positioned in the non-display area NDA before the light-emitting elements LD are aligned in the emission area EMA of each pixel PXL.

The first electrode EL1 may be used as a first alignment electrode by receiving a first alignment signal in an operation of aligning the light-emitting elements LD. The second electrode EL2 may be used as a second alignment electrode by receiving a second alignment signal in the operation of aligning the light-emitting elements LD. In the above-described operation of aligning the light-emitting elements LD, the third electrode EL3 may be electrically connected to the second electrode EL2 and used as the second alignment electrode. The fourth electrode EL4 may be used as a third alignment electrode by receiving a third alignment signal in the operation of aligning the light-emitting elements LD. The above-described first to third alignment signals may be signals having a voltage difference and/or a phase difference such that the light-emitting elements LD may be aligned between the first to fourth electrodes EL1 to EL4. At least one of the first to third alignment signals may be an alternating current (AC) signal, and the third alignment signal may be identical to the first alignment signal, but the disclosure is not limited thereto.

According to embodiments, in order to change surface profiles (or shapes) of the first to fourth electrodes EL1 to EL4 to guide light, emitted by the light-emitting elements LD, in the image display direction (or the front direction) of the display device DD, each of the pixels PXL may include support members for supporting the first to fourth electrodes EL1 to EL4. The above-described support members may include a first-first bank pattern BNKP1_1 overlapping an area of the first-first electrode EL1_1, a first-second bank pattern BNKP1_2 overlapping an area of the first-second electrode EL1_2, a second bank pattern BNKP2 overlapping each of an area of the second electrode EL2 and an area of the third electrode EL3, a third-first bank pattern BNKP3_1 overlapping an area of the fourth-first electrode EL4_1, and a third-second bank pattern BNKP3_2 overlapping an area of the fourth-second electrode EL4_2.

The second bank pattern BNKP2 may extend in the second direction DR2. The first-first bank pattern BNKP1_1 and the third-first bank pattern BNKP3_1 may be spaced apart from the second bank pattern BNKP2 in different directions, the first-second bank pattern BNKP1_2 may be spaced apart from the first-first bank pattern BNKP1_1 in the second direction DR2, and the third-second bank pattern BNKP3_2 may be spaced apart from the third-first bank pattern BNKP3_1 in the second direction DR2.

The first-first bank pattern BNKP1_1 may make an area of the first-first electrode EL1_1 protrude upward, the first-second bank pattern BNKP1_2 may make an area of the first-second electrode EL1_2 protrude upward, the third-first bank pattern BNKP3_1 may make an area of the fourth-first electrode EL4_1 protrude upward, and the third-second bank pattern BNKP3_2 may make an area of the fourth-second electrode EL4_2 protrude upward. The second bank pattern BNKP2 may make an area of the second electrode EL2 and an area of the third electrode EL3 protrude upward.

The pixel PXL may include the light-emitting elements LD. At least two to tens of the light-emitting elements LD may be aligned and/or provided or disposed in the pixel area PXA, but the number of the light-emitting elements LD is not limited thereto. According to embodiments, the number of the light-emitting elements LD aligned and/or provided or disposed in the pixel area PXA may be variously changed.

The light-emitting elements LD may include first light-emitting elements LD1, second light-emitting elements LD2, third light-emitting elements LD3, and fourth light-emitting elements LD4. According to embodiments, each pixel PXL may further include the reverse light-emitting element LDr described with reference to FIG. 4.

The first light-emitting element LD1 may be disposed between the first-first electrode EL1_1 and the second-first electrode EL2_1 of each pixel PXL. Here, the term “between” may mean a case where at least an area of the first light-emitting element LD1 overlaps the first-first and second-first electrodes EL1_1 and EL2_1, but the disclosure is limited thereto. For example, the first light-emitting element LD1 may be spaced apart from the first-first and second-first electrodes EL1_1 and EL2_1 by a distance in a plan view. A first end portion EP1 of the first light-emitting element LD1 may face the first-first electrode EL1_1, and a second end portion EP2 of the first light-emitting element LD1 may face the second-first electrode EL2_1. In case that first light-emitting elements LD1 are provided, the first light-emitting elements LD1 may be electrically connected in parallel between the first-first electrode EL1_1 and the second-first electrode EL2_1 and may constitute the first series stage SET1 described with reference to FIG. 4.

The second light-emitting element LD2 may be disposed between the first-second electrode EL1_2 and the second-second electrode EL2_2 of the corresponding pixel PXL. A first end portion EP1 of the second light-emitting element LD2 may face the first-second electrode EL1_2, and a second end portion EP2 of the second light-emitting element LD2 may face the second-second electrode EL2_2. In case that second light-emitting elements LD2 are provided, the second light-emitting elements LD1 may be electrically connected in parallel between the first-second electrode EL1_2 and the second-second electrode EL2_2 and may constitute the second series stage SET2 described with reference to FIG. 4.

The third light-emitting element LD3 may be disposed between the third-second electrode EL3_2 and the fourth-second electrode EL4_2 of the corresponding pixel PXL. A first end portion EP1 of the third light-emitting element LD3 may face the fourth-second electrode EL4_2, and a second end portion EP2 of the third light-emitting element LD3 may face the third-second electrode EL3_2. In case that third light-emitting elements LD3 are provided, the third light-emitting elements LD3 may be electrically connected in parallel between the third-second electrode EL3_2 and the fourth-second electrode EL4_2 and may constitute the third series stage SET3 described with reference to FIG. 4.

The fourth light-emitting element LD4 may be disposed between the third-first electrode EL3_1 and the fourth-first electrode EL4_1 of the corresponding pixel PXL. A first end portion EP1 of the fourth light-emitting element LD4 may face the fourth-first electrode EL4_1, and a second end portion EP2 of the fourth light-emitting element LD4 may face the third-first electrode EL3_1. In case that fourth light-emitting elements LD4 are provided, the fourth light-emitting elements LD4 may be electrically connected in parallel between the third-first electrode EL3_1 and the fourth-first electrode EL4_1 and may constitute the fourth series stage SET4 described with reference to FIG. 4.

In an embodiment, the first end portion EP1 of the first light-emitting element LD1, the first end portion EP1 of the second light-emitting element LD2, the first end portion EP1 of the third light-emitting element LD3, and the first end portion EP1 of the fourth light-emitting element LD4 may include a same type semiconductor layer (for example, the second semiconductor layer 13 described with reference to FIG. 1). In an embodiment, the second end portion EP2 of the first light-emitting element LD1, the second end portion EP2 of the second light-emitting element LD2, the second end portion EP2 of the third light-emitting element LD3, and the second end portion EP2 of the fourth light-emitting element LD4 may include a same type semiconductor layer (for example, the first semiconductor layer 11 described with reference to FIG. 1).

According to embodiments, each of the first light-emitting element LD1, the second light-emitting element LD2, the third light-emitting element LD3, and the fourth light-emitting element LD4 may be a micro-light-emitting diode using a material having an inorganic crystalline structure, and having, for example, a small size to a degree of the nanoscale to the microscale. For example, each of the first light-emitting element LD1, the second light-emitting element LD2, the third light-emitting element LD3, and the fourth light-emitting element LD4 may be the light-emitting element LD described with reference to FIGS. 1 and 2. Each of the light-emitting elements LD may emit color light and/or white light.

The light-emitting elements LD may be dispersed in a solution (or ink) and may be introduced (or supplied) to the emission area EMA of each pixel PXL. The light-emitting elements LD may be introduced (or supplied) to the emission area EMA of each pixel PXL by an inkjet printing method, a slit coating method, or various other methods. As an example, the light-emitting elements LD may be mixed with a volatile solvent and introduced (or supplied) to the emission area EMA by the inkjet printing method or the slit coating method. In case that an alignment signal corresponding to each of the first to fourth electrodes EL1 to EL4 is applied thereto, an electric field may be formed between two adjacent electrodes of the first to fourth electrodes EL1 to EL4. Therefore, the light-emitting elements LD may be aligned between two adjacent electrodes of the first to fourth electrodes EL1 to EL4. As described above, since a same alignment signal is applied to the second and third electrodes EL2 and EL3, the light-emitting elements LD may not be aligned between the second electrode EL2 and the third electrode EL3. However, the disclosure is not limited thereto. According to embodiments, in case that an alignment signal is applied to each of the second and third electrodes EL2 and EL3, a potential difference may occur between the alignment signals applied to the second electrode EL2 and the third electrode EL3 because of line resistance of the two electrodes, an influence of an electric field induced between adjacent electrodes, or the like within the spirit and the scope of the disclosure. The light-emitting elements LD may be aligned between the second electrode EL2 and the third electrode EL3. By volatilizing the solvent or removing the solvent by other methods after the light-emitting elements LD are aligned, the light-emitting elements LD may be stably aligned between the first to fourth electrodes EL1 to EL4.

According to embodiments, each pixel PXL may include a first contact electrode CNE1, a second contact electrode CNE2, a first intermediate electrode CTE1, a second intermediate electrode CTE2, and a third intermediate electrode CTE3. The first contact electrode CNE1, the second contact electrode CNE2, the first intermediate electrode CTE1, the second intermediate electrode CTE2, and the third intermediate electrode CTE3 may be spaced apart from each other in a plan view.

The first contact electrode CNE1 may be formed on the first end portion EP1 of the first light-emitting element LD1 and at least one area or an area of the first-first electrode EL1_1 corresponding thereto to physically and/or electrically connect the first end portion EP1 of the first light-emitting element LD1 to the first-first electrode EL1_1.

The first contact electrode CNE1 may have a substantially bar-like shape extending in the second direction DR2 in a plan view, but the disclosure is not limited thereto. According to embodiments, a shape of the first contact electrode CNE1 may be variously changed within a range in which the first contact electrode CNE1 is electrically and stably connected to the first end portion EP1 of the first light-emitting element LD1. The shape of the first contact electrode CNE1 may be variously changed in consideration of a connection relationship with the first electrode EL1 disposed under or below the first contact electrode CNE1.

The second contact electrode CNE2 may be disposed on the second end portion EP2 of the fourth light-emitting elements LD4 and at least one area or an area of the third-first electrode EL3_1 corresponding thereto to physically and/or electrically connect the second end portion EP2 of the fourth light-emitting element LD4 to the third-first electrode EL3_1.

The first intermediate electrode CTE1 may include a first-first intermediate electrode CTE11 and a first-second intermediate electrode CTE12 which extend in the second direction DR2. The first-first intermediate electrode CTE1_1 may be formed on the second end portion EP2 of the first light-emitting element LD1 and at least one area or an area of the second-first electrode EL2_1 corresponding thereto. The first intermediate electrode CTE1 may extend from the second-first electrode EL2_1 (or the first-first intermediate electrode CTE1_1) to the first-second electrode EL1_2 (or the first-second intermediate electrode CTE1_2). The first-second intermediate electrode CTE1_2 may be formed on the first end portion EP1 of the second light-emitting element LD2 and at least one area or an area of the first-second electrode EL1_2 corresponding thereto. The first intermediate electrode CTE1 may electrically connect the second end portion EP2 of the first light-emitting element LD1 and the first end portion EP1 of the second light-emitting element LD2. For example, the first intermediate electrode CTE1 may be a first bridge electrode (or a first connection electrode) for electrically connecting the first series stage SET1 and the second series stage SET2.

The second intermediate electrode CTE2 may include a second-first intermediate electrode CTE2_1 and a second-second intermediate electrode CTE2_2 which extend in the second direction DR2. The second-first intermediate electrode CTE2_1 may be formed on the second end portion EP2 of the second light-emitting element LD2 and at least one area or an area of the second-second electrode EL2_2 corresponding thereto. The second intermediate electrode CTE2 may bypass the third intermediate electrode CTE3 or the third light-emitting element LD3 and extend from the second-second electrode EL2_2, and the second-second intermediate electrode CTE2_2 may be formed on the first end portion EP1 of the third light-emitting element LD3 and at least one area or an area of the fourth-second electrode EL4_2 corresponding thereto. The second intermediate electrode CTE2 may electrically connect the second end portion EP2 of the second light-emitting element LD2 and the first end portion EP1 of the third light-emitting element LD3. For example, the second intermediate electrode CTE2 may be a second bridge electrode (or a second connection electrode) for electrically connecting the second series stage SET2 and the third series stage SET3.

The third intermediate electrode CTE3 may include a third-first intermediate electrode CTE3_1 and a third-second intermediate electrode CTE3_2 which extend in the second direction DR2. The third-first intermediate electrode CTE3_1 may be formed on the second end portion EP2 of the third light-emitting element LD3 and at least one area or an area of the third-second electrode EL3_2 corresponding thereto. The third intermediate electrode CTE3 may extend from the third-second electrode EL3_2 (or the third-first intermediate electrode CTE3_1) to the fourth-first electrode EL4_1 (or the third-second intermediate electrode CTE3_2). The third-second intermediate electrode CTE3_2 may be formed on the first end portion EP1 of the fourth light-emitting element LD4 and at least one area or an area of the fourth-first electrode EL4_1 corresponding thereto. The third intermediate electrode CTE3 may electrically connect the second end portion EP2 of the third light-emitting element LD3 and the first end portion EP1 of the fourth light-emitting element LD4. For example, the third intermediate electrode CTE3 may be a third bridge electrode (or a third connection electrode) for electrically connecting the third series stage SET3 and the fourth series stage SET4.

Each of the first contact electrode CNE1, the second contact electrode CNE2, the first intermediate electrode CTE1, the second intermediate electrode CTE2, and the third intermediate electrode CTE3 may be made of various transparent conductive materials to allow light, which is emitted by each of the light-emitting elements LD and reflected by the first to fourth electrodes EL1 to EL4, to travel in an image display direction of the display device DD without loss.

The first to third intermediate electrodes CTE1 to CTE3 may be provided or disposed in an identical layer to or to be coplanar with the first and second contact electrodes CNE1 and CNE2 and may be formed by a same process. However, the disclosure is not limited thereto, and according to the embodiments, at least one of the first to third intermediate electrodes CTE1 to CTE3 may be provided or disposed in a different layer from the first and second contact electrodes CNE1 and CNE2 and may be formed by a different process.

As described above, the first light-emitting element LD1 may be electrically connected in series to the second light-emitting element LD2 by the first intermediate electrode CTE1, the second light-emitting element LD2 may be electrically connected in series to the third light-emitting element LD3 by the second intermediate electrode CTE2, and the third light-emitting element LD3 may be electrically connected in series to the fourth light-emitting element LD4 by the third intermediate electrode CTE3.

During each frame period, in each pixel PXL, a driving current may flow from the first-first electrode EL1_1 to the third-first electrode EL3_1 through the first light-emitting element LD1, the first intermediate electrode CTE1, the second light-emitting element LD2, the second intermediate electrode CTE2, the third light-emitting element LD3, the third intermediate electrode CTE3, and the fourth light-emitting element LD4.

The first light-emitting element LD1, the second light-emitting element LD2, the third light-emitting element LD3, and the fourth light-emitting element LD4 may be electrically connected in series between the first-first electrode EL1_1 and the third-first electrode EL3_1 through the first intermediate electrode CTE1, the second intermediate electrode CTE2, and the third intermediate electrode CTE3. In such an arrangement, the light-emitting elements LD arranged or disposed in the pixel area PXA of each pixel PXL may be electrically connected in a series-parallel combination structure to constitute the light-emitting unit EMU of the pixel PXL. Therefore, while an area occupied by the alignment electrodes is minimized (or the number of the alignment electrodes is not increased), the light-emitting unit EMU may be formed in a series-parallel combination structure including four series stages, and thus a high-resolution and high-definition display device DD may be readily implemented.

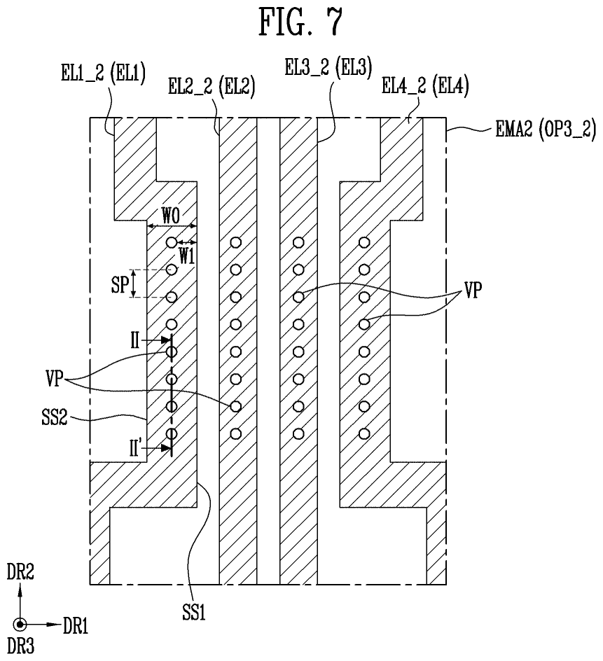

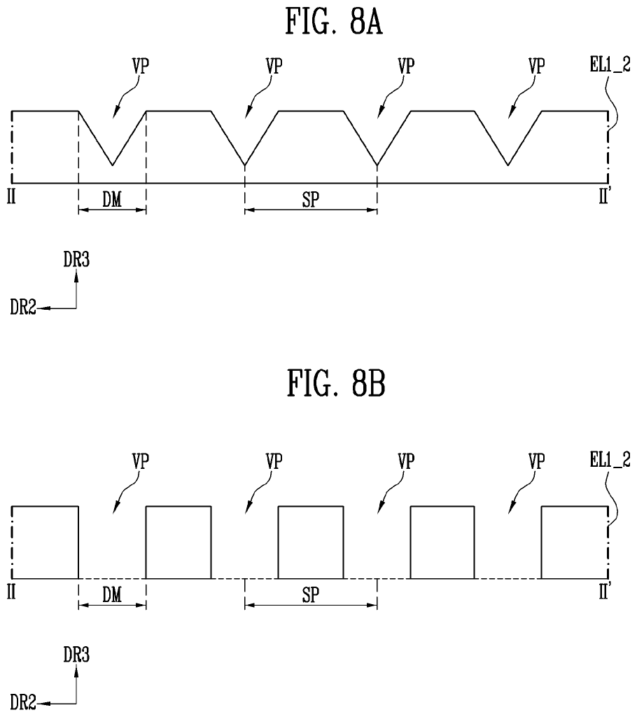

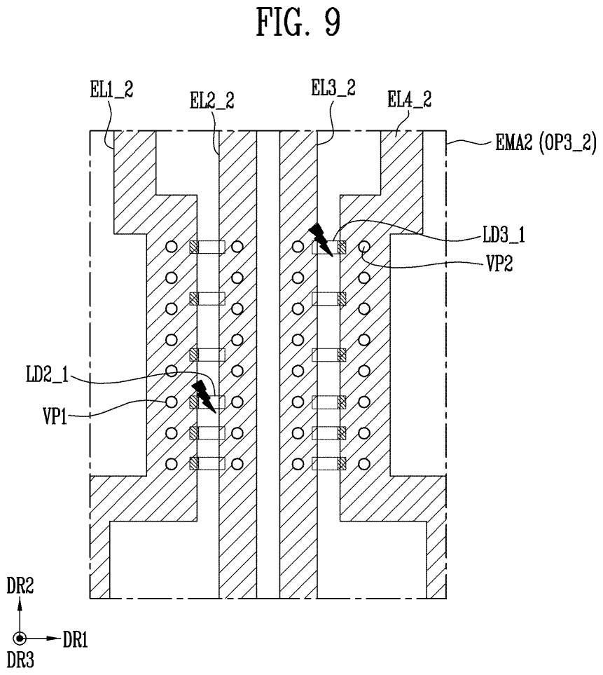

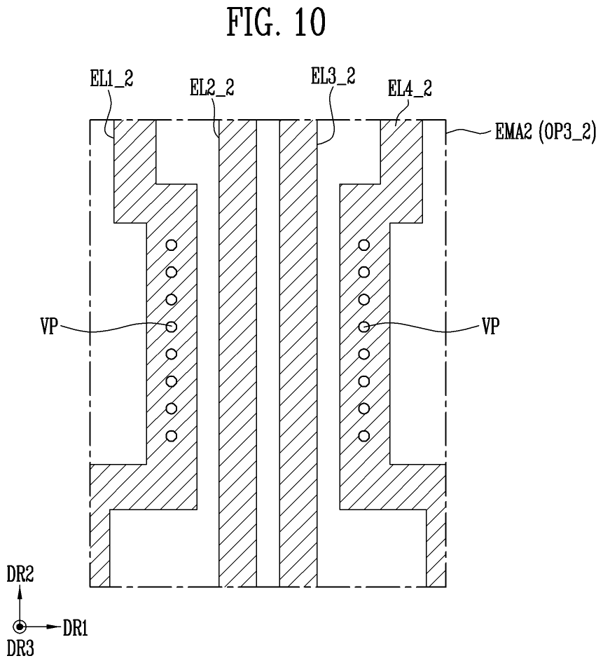

FIG. 7 is a schematic plan view illustrating electrodes included in the pixel of FIG. 6 according to an embodiment. FIGS. 8A and 8B are schematic cross-sectional views taken along line II-IF of FIG. 7 which illustrate an electrode according to an embodiment. FIG. 9 is a schematic plan view illustrating the electrodes and light-emitting elements included in the pixel of FIG. 6 according to an embodiment.

Referring to FIGS. 5 to 9, at least one of a first-second electrode EL1_2 (or a first electrode EL1), a second-second electrode EL2_2 (or a second electrode EL2), a third-second electrode EL3_2 (or a third electrode EL3), and a fourth-second electrode EL4_2 (or a fourth electrode EL4) may have markings VP (or void patterns or graduations) formed in an extending direction (or a first extending direction) in which each electrode extends. For example, as shown in FIG. 7, each of the first-second electrode EL1_2, the second-second electrode EL2_2, the third-second electrode EL3_2, and the fourth-second electrode EL4_2 may have the markings VP in a second direction DR2.

Since the markings VP formed on each of the first-second electrode EL1_2, the second-second electrode EL2_2, the third-second electrode EL3_2, and the fourth-second electrode EL4_2 may be substantially identical or similar to each other, the markings VP formed on the first-second electrode EL12 will be described below.

In an embodiment, each of the markings VP may be a pattern concavely or convexly formed on an upper surface of the first-second electrode EL1_2. For example, as shown in FIG. 8A, each of the markings VP may be a pattern concavely on an upper surface of the first-second electrode EL1_2. In an embodiment, as shown in FIG. 8B, each of the markings VP may be a hole (or an opening) passing through the first-second electrode EL1_2.

The markings VP may be spaced apart from each other by same intervals SP over an entire section corresponding to light-emitting elements LD (see FIG. 6) in the second direction DR2 (or the first extending direction). For example, the markings VP may be arranged or disposed in the second direction DR2 at the intervals SP of about 4 μm to about 10 μm or of about 5 μm.

As will be described below, the markings VP may be used to specify or determine positions of the light-emitting elements LD at an electrode (for example, the first-second electrode EL1_2) which the light-emitting elements LD contact or correspond thereto. For example, the markings VP may be used to specify the position of the light-emitting element LD in which a defect (for example, a short circuit) has occurred. For example, each of the markings VP may be a division line drawn on the electrode to read the position of the light-emitting element LD.

Referring to FIG. 9, for example, in case that a defect occurs in a second-first light-emitting element LD2_1, the position of the second-first light-emitting element LD2_1 may be determined by a first marking VP1. For example, in case that coordinate information (or coordinates) of the first marking VP1 is preset within a corresponding pixel PXL, coordinate information of the second-first light-emitting element LD2_1 may be determined on the basis of the coordinate information of the first marking VP1. Likewise, in case that a defect occurs in a third-first light-emitting element LD3_1, the position of the third-first light-emitting element LD3_1 may be determined by a second marking VP2.

For reference, in a heat generation test operation, a light-emitting element in which a defect has occurred among the light-emitting elements LD may be detected on the basis of a heat generation state according to a current flowing in the light-emitting elements LD and/or resistance. For example, in case that the second-first light-emitting element LD2_1 is short-circuited, a greater amount of current than other second light-emitting elements LD2 may flow in the second-first light-emitting element LD2_1, and the second-first light-emitting element LD2_1 may emit more heat than the other light-emitting elements LD2. Therefore, it is possible to detect that a defect has occurred in the second-first light-emitting element LD2_1. In a repair operation after the heat generation test operation, an accurate position of the second-first light-emitting element LD2_1 may be required to repair the pixel PXL including the second-first light-emitting element LD2_1.

However, in case that no markings VP are formed, the pixel PXL may have no separate reference point (for example, a reference point for specifying the position of a first light-emitting element LD1), and thus the position of the second light-emitting element LD2 may not be accurately specified.

For example, according to embodiments, through the markings VP formed on the electrode (for example, the first-second electrode EL1_2) which the light-emitting elements LD contact or correspond thereto, the positions of the light-emitting elements LD, for example, the position of a light-emitting element (for example, the second-first light-emitting element LD2_1) in which a defect has occurred may be accurately specified in the corresponding pixel PXL or a series stage, and the corresponding pixel PXL may be repaired by a method or the like of cutting the second-first light-emitting element LD2_1 by using a laser.

In an embodiment, each of the markings VP may have a circular or substantially rectangular planar shape. For example, as shown in FIG. 7, each of the markings VP may have a substantially circular planar shape. A diameter DM (or a width in the second direction DR2) of each of the markings VP may have a minimum size at which the marking VP may be machined or a minimum size at which the marking VP may be visually recognized by an imaging device. For example, the diameter DM may be about 1 μm.

In an embodiment, in a plan view, the position of each of the markings VP of the first-second electrode EL1_2 may be determined by Equation 1 below.

⅓W0≤W1≤½W0 [Equation 1]

Here, W0 may refer to a distance by which each of the markings VP is spaced apart from a first side SS1 of the first-second electrode EL1_2 in a first direction DR1, and W1 may refer to a width of the first-second electrode EL1_2 in the first direction DR1. The first side SS1 may be a side of the first-second electrode EL1_2 facing the second-second electrode EL2_2. The first direction DR1 may be a direction perpendicular to an extending direction of the first-second electrode EL12.

Likewise, the positions of the markings VP in each of the second electrode EL2, the third electrode EL3, and the fourth-second electrode EL4_2 may also be determined by Equation 1. W0 in Equation 1 may refer to a distance by which the markings VP are spaced apart from a side (for example, a side of a corresponding electrode) facing the light-emitting element LD (for example, of the light-emitting element LD2 or LD3 (see FIG. 6)), in the first direction DR1, and W1 in Equation 1 may refer to a width of the corresponding electrode in the first direction DR1.

Each of the markings VP may be positioned closer to the first side SS1 than to a second side SS2 (for example, a side opposite to the first side SS1) of the first-second electrode EL1_2.

For reference, the light-emitting elements LD may be aligned between the first to fourth electrodes EL1 to EL4 based on electro-osmosis or AC electro-osmosis due to an electric field formed between the first to fourth electrodes EL1 to EL4. The markings VP formed on at least one of the first to fourth electrodes EL1 to EL4 may affect the electric field and the electro-osmosis. Therefore, in case that the position of each of the markings VP is determined by Equation 1, the influence of the markings VP on the electric field and the electro-osmosis may be minimized.

However, the position of each of the markings VP is not limited thereto. For example, as the diameter DM of each of the markings VP is decreased, the influence of the markings VP on the electric field and electro-osmosis may be further decreased. The markings VP may be positioned closer to the second side SS2 of the first-second electrode EL1_2.

As described above, the markings VP may be formed on at least one of the first to fourth electrodes EL1 to EL4 constituting the first to fourth serial stages SET1 to SET4 of the pixel PXL, and the position of the light-emitting element (for example, the second-first light-emitting element LD2_1), in which a defect has occurred, may be accurately specified based on the markings VP, and the corresponding pixel PXL may be accurately repaired by a method or the like of cutting the second-first light-emitting element LD2_1 by using a laser.

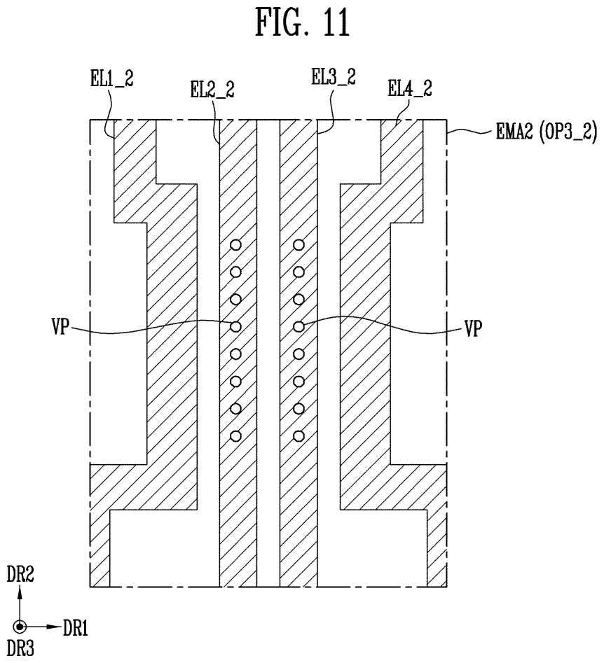

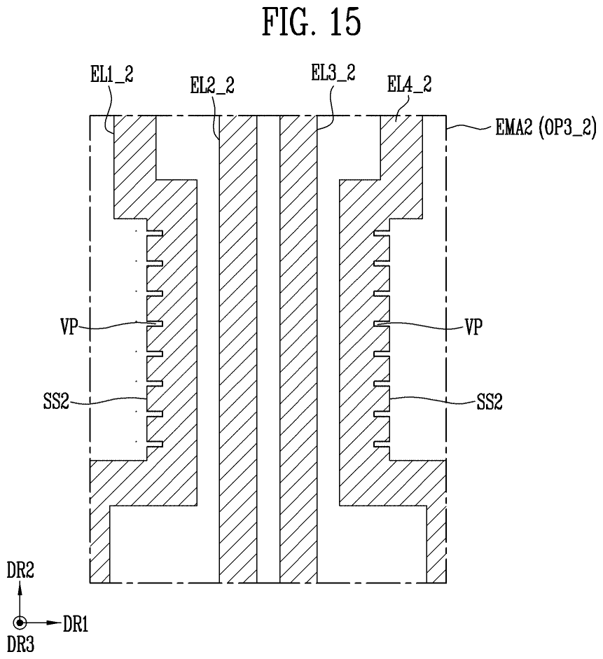

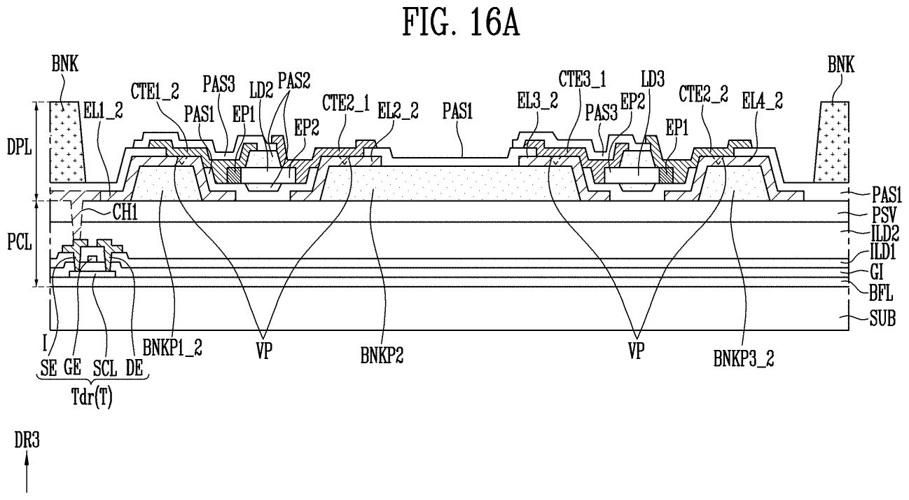

FIGS. 10, 11, 12, 13, 14, and 15 are schematic plan views illustrating electrodes included in the pixel of FIG. 6 according to various embodiments. FIGS. 10 to 15 are views corresponding to FIG. 7.

Referring to FIGS. 5 to 15, since a first-first electrode EL1_1, a second-first electrode EL2_1, a third-first electrode EL3_1, and a fourth-first electrode EL4_1 in a first emission area EMA1 are substantially identical or similar to a first-second electrode EL1_2, a second-second electrode EL2_2, a third-second electrode EL3_2, and a fourth-second electrode EL4_2 in second emission area EMA2, the first-second electrode EL1_2, the second-second electrode EL2_2, the third-second electrode EL3_2, and the fourth-second electrode EL4_2 will be described below.

Except for the shapes and positions of markings VP, the first-second electrode EL1_2, the second-second electrode EL2_2, the third-second electrode EL3_2, and the fourth-second electrode EL4_2 have been described with reference to FIGS. 5 to 9, and thus, repetitive descriptions thereof will not be repeated.

As shown in FIG. 10, the markings VP may be formed only on the first-second electrode EL1_2 and the fourth-second electrode EL4_2 adjacent to an edge of the second emission area EMA2 in a first direction DR1 and may not be formed on the second-second electrode EL2_2 and the third-second electrode EL3_2 adjacent to an area center of the second emission area EMA2. On the other hand, as shown in FIG. 11, the markings VP may be formed only on the second-second electrode EL2_2 and the third-second electrode EL3_2 and may not be formed on the first-second electrode EL1_2 and the fourth-second electrode EL4_2. For example, even in case that the markings VP are formed only on one of two pairs of electrodes (for example, the first-second electrode EL1_2 and the second-second electrode EL2_2, or the third-second electrode EL3_2 and the fourth-second electrode EL4_2) constituting a series terminal, the positions of light-emitting elements LD may be specified.

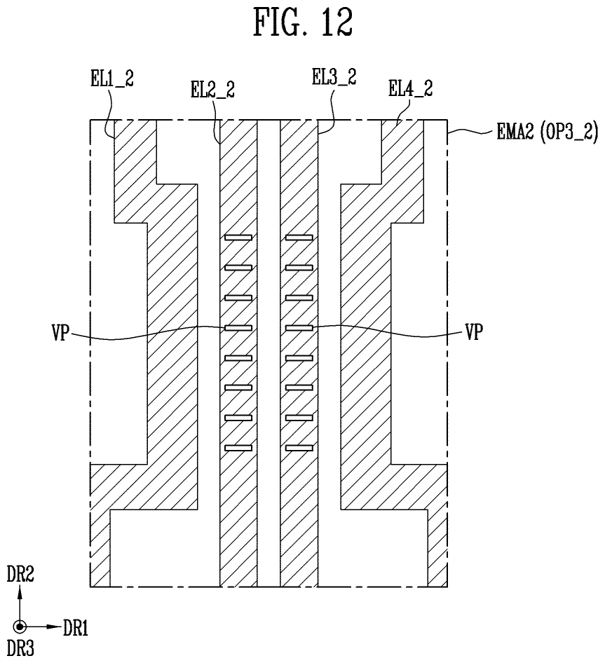

As illustrated in FIG. 12, each of the markings VP may have a substantially quadrangular or substantially rectangular planar shape or may also have a line shape extending substantially in a first direction DR1. The makings VP may have a same length in the first direction DR1, but the disclosure is not limited thereto. For example, some or a number of the markings VP may have different lengths in the first direction DR1.

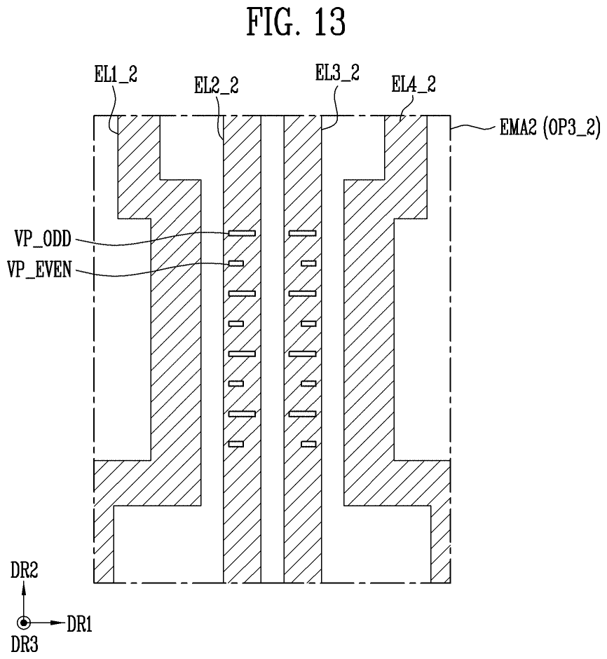

As shown in FIG. 13, odd-numbered markings VP_ODD and even-numbered markings VP_EVEN may be alternately arranged or disposed each other in a second direction DR2, and a length of the odd-numbered markings VP_ODD in the first direction DR1 may be greater than that of the even-numbered markings VP_EVEN in the first direction DR1. The position of the light-emitting element LD may be approximately specified by the odd-numbered markings VP_ODD, and the position of the light-emitting element LD may be accurately specified by the adjacent even-numbered markings VP_EVEN. For example, the positions of the light-emitting elements LD may be more intuitively identified.

FIG. 13 illustrates that the relatively long marking and the relatively short marking are alternately arranged or disposed each other, but the disclosure is not limited thereto. For example, only a marking (for example, a first marking) may be longer than other markings. As another example, markings may be disposed between relatively long and adjacent markings.

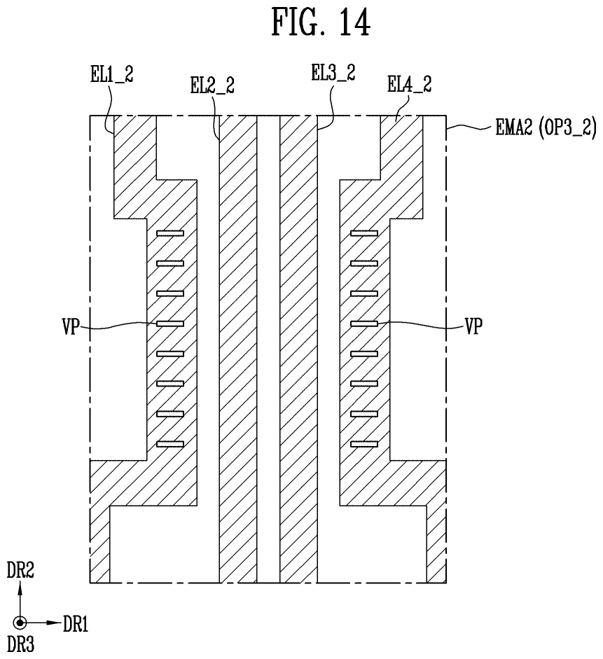

FIGS. 12 and 13 illustrate that the markings VP are formed on the second-second electrode EL2_2 and the third-second electrode EL3_2, but the disclosure is not limited thereto. For example, as shown in FIG. 14, the markings VP having a substantially quadrangular or substantially rectangular planar shape or a line shape may be formed on the first-second electrode EL1_2 and the fourth-second electrode EL4_2.

In an embodiment, in a plan view, the markings VP may contact a second side SS2 of the first-second electrode EL1_2. In consideration of an influence on an electric field formed between the first-second electrode EL1_2, the second-second electrode EL2_2, the third-second electrode EL3_2, and the fourth-second electrode EL4_2, the markings VP may be formed closest to an edge of the second emission area EMA2 in the first direction DR1. The first-second electrode EL1_2 may have a substantially comb shape in a plan view. Likewise, in a plan view, the markings VP may contact a second side SS2 of the fourth-second electrode EL4_2.

As described above, the markings VP may be formed on some or a number of the first to fourth electrodes EL1 to EL4 constituting first to fourth series stages SET1 to SET4 of a pixel PXL, the markings VP may have a substantially quadrangular or substantially rectangular planar shape (or a line shape or substantially linear shape) other than a substantially circular shape, and according to embodiments, the markings VP may contact a specific side or a side of each of the first to fourth electrodes EL1 to EL4.

On the other hand, FIGS. 10 to 15 illustrate that the markings VP have a substantially circular or substantially quadrangular or substantially rectangular planar shape, but the planar shape of the markings VP may be variously changed within a range in which the markings VP may be identified by an imaging device. For example, the markings VP may have a planar shape such as a substantially triangular, semicircular, or elliptic shape.

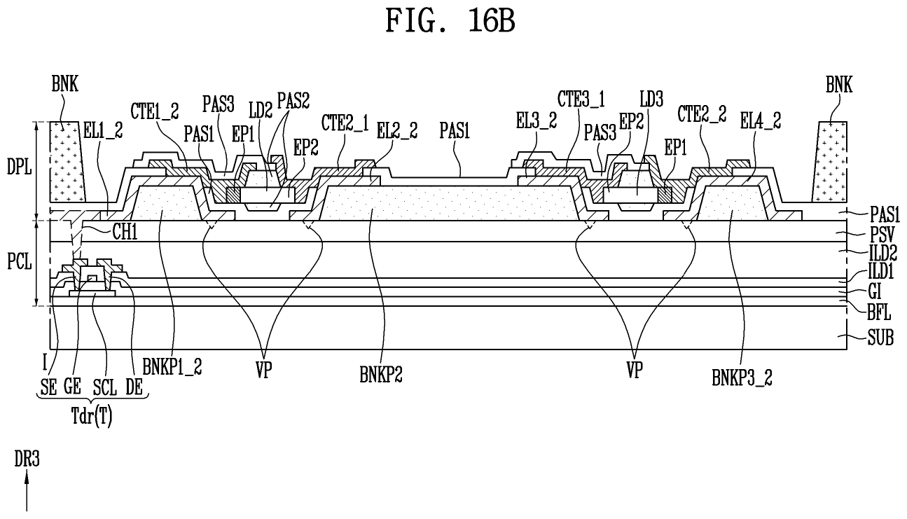

Hereinafter, a stacked structure of each pixel PXL according to the above-described embodiment will be described with reference to FIGS. 16A and 16B.

FIGS. 16A and 16B are schematic cross-sectional views taken along line I-I′ of FIG. 6 which illustrate a pixel according to an embodiment. FIGS. 16A and 16B illustrate that each electrode is a single-film electrode, and each insulating layer is a single-film insulating layer to simplify a pixel PXL, but the disclosure is not limited thereto.

Referring to FIGS. 3, 5, 6, 16A, and 16B, a stacked structure in a first emission area EMA1 may be substantially identical or similar to that in a second emission area EMA2, and thus, the stacked structure in the second emission area EMA2 will be described below.

A pixel circuit layer PCL and a display element layer DPL (or a light-emitting element layer) may be sequentially disposed on a substrate SUB. According to embodiments, the pixel circuit layer PCL and the display element layer DPL may be entirely formed in a display area DA of a display device DD.

The pixel circuit layer PCL may include a buffer layer BFL, a transistor T, and a protective layer PSV. As shown in FIG. 16A, the buffer layer BFL, the transistor T, and the protective layer PSV may be sequentially stacked each other on the substrate SUB.

The buffer layer BFL may prevent impurities from diffusing into the transistor T. The buffer layer BFL may be an inorganic insulating film including an inorganic material. The inorganic insulating film may include, for example, at least one of metal oxides such as silicon nitride (SiNₓ), silicon oxide (SiOₓ), silicon oxynitride (SiOₓN_{y}), and aluminum oxide (AlOₓ). The buffer layer BFL may be provided as a single film and may also be provided as multiple films including at least two films In case that the buffer layer BFL is provided as multiple films, respective layers may be made of a same material or similar material or different materials. The buffer layer BFL may be omitted according to the material and process conditions of the substrate SUB.

The transistor T may include a driving transistor Tdr that controls driving currents of second and third light-emitting elements LD2 and LD3. The driving transistor Tdr may be the first transistor T1 described with reference to FIG. 4. In addition to the driving transistor Tdr, the transistor T may further include the second transistor T2 and the third transistor T3 described with reference to FIG. 4.

The driving transistor Tdr may include a semiconductor pattern SCL, a gate electrode GE, a first terminal DE, and a second terminal SE. The first terminal DE may be one of a source electrode and a drain electrode, and the second terminal SE may be the other. As an example, in case that the first terminal DE is a drain electrode, the second terminal SE may be a source electrode.

The semiconductor pattern SCL may be provided and/or formed or disposed on the buffer layer BFL. The semiconductor pattern SCL may include a first contact region contacting the first terminal DE and a second contact region contacting the second terminal SE. A region between the first contact region and the second contact region may be a channel region. The channel region may overlap the gate electrode GE of the corresponding transistor T. The semiconductor pattern SCL may be a semiconductor pattern made of polysilicon, amorphous silicon, an oxide semiconductor, or the like within the spirit and the scope of the disclosure. The channel region may be, for example, a semiconductor pattern that is doped with no impurities and may be an intrinsic semiconductor. The first contact region and the second contact region may be semiconductor patterns doped with impurities.

A gate insulating layer GI may be provided and/or formed or disposed on the semiconductor pattern SCL. The gate insulating layer GI may be an inorganic insulating film including an inorganic material. As an example, the gate insulating layer GI and the buffer layer BFL may include a same material or similar material, or the gate insulating layer GI may include at least one material selected from the materials of the buffer layer BFL. According to embodiments, the gate insulating layer GI may be formed as an organic insulating film including an organic material. The gate insulating layer GI may be provided as a single film and may also be provided as multiple films including at least two films.

The gate electrode GE may be provided and/or formed or disposed on the gate insulating layer GI so as to correspond to the channel region of the semiconductor pattern SCL. The gate electrode GE may be provided or disposed on the gate insulating layer GI to overlap the channel region of the semiconductor pattern SCL. The gate electrode GE may have a single-film structure made of at least one selected from the group consisting of copper (Cu), molybdenum (Mo), tungsten (W), aluminum neodymium (AlNd), titanium (Ti), aluminum (Al), silver (Ag), and an alloy thereof, or a mixture thereof or may have a double- or multi-film structure including a low resistance material, such as molybdenum (Mo), titanium (Ti), copper (Cu), aluminum (Al), or silver (Ag) in order to reduce line resistance.

A first interlayer insulating layer ILD1 may be provided and or formed or disposed on the gate insulating layer GI. The first interlayer insulating layer ILD1 and the gate insulating layer GI may include a same material or similar material, or the first interlayer insulating layer ILD1 may include at least one material selected from the materials of the gate insulating layer GI.

The first terminal DE and the second terminal SE may be provided and/or formed or disposed on the first interlayer insulating layer ILD1 and may contact the first contact region and the second contact region of the semiconductor pattern SCL through contact holes sequentially passing through the gate insulating layer GI and the first interlayer insulating layer ILD1. Each of the first and second terminals DE and SE and the gate electrode GE may include a same material or similar material, or each of the first and second terminals DE and SE may include at least one selected from the materials of the gate electrode GE.

In the above-described embodiment, it has been described that the first and second terminals DE and SE of the driving transistor Tdr are separate electrodes electrically connected to the semiconductor pattern SCL through the contact holes sequentially passing through the gate insulating layer GI and the first interlayer insulating layer ILD1, but the disclosure is not limited thereto. According to embodiments, the first terminal DE of the driving transistor Tdr may be the first contact region adjacent to the channel region of the corresponding semiconductor pattern SCL, and the second terminal SE of each of the driving transistor Tdr and the switching transistor T2 may be the second contact region adjacent to the channel region of the corresponding semiconductor pattern SCL. The second terminal SE of the driving transistor Tdr may be electrically connected to the second and third light-emitting elements LD2 and LD3 of the corresponding pixel PXL through a separate connection means such as a bridge electrode or the like within the spirit and the scope of the disclosure.

In an embodiment, the transistor T may be formed as a low-temperature polysilicon (LTPS) thin-film transistor, but the disclosure is not limited thereto. According to embodiments, the transistor T may be formed as an oxide semiconductor thin-film transistor. Furthermore, a case where the transistor T is a thin-film transistor having a top gate structure has been described as an example, but the disclosure is not limited thereto. The structure of the transistor T may be variously changed.

A second interlayer insulating layer ILD2 may be provided and/or formed or disposed on the transistor T. The second interlayer insulating layer ILD2 and the gate insulating layer GI may include a same material or similar material, or the second interlayer insulating layer ILD2 may include at least one material selected from the materials of the gate insulating layer GI. The second interlayer insulating layer ILD2 may be omitted according to embodiments.

The protective layer PSV may be provided and/or formed or disposed on the second interlayer insulating layer ILD2.

The protective layer PSV may include an organic insulating film, an inorganic insulating film, or an organic insulating film disposed on an inorganic insulating film. The inorganic insulating film may include, for example, at least one selected from metal oxides such as silicon oxide (SiOₓ), silicon nitride (SiNₓ), silicon oxynitride (SiOₓN_{y}), and aluminum oxide (AlOₓ). The organic insulating film may include, for example, at least one selected from an acrylic-based resin (a polyacrylate-based resin), an epoxy-based resin, a phenolic-based resin, a polyamide-based resin, a polyimide-based resin, an unsaturated polyester-based resin, a polyphenylen ether-based resin, a polyphenylene sulfide-based resin, and a benzocyclobutene resin.

The protective layer PSV (and the second interlayer insulating layer ILD2) may include a first contact hole CH1 exposing the second terminal SE of the driving transistor Tdr.

The display element layer DPL may include a first-second bank pattern BNKP1_2, a second bank pattern BNKP2, a third-second bank pattern BNKP3_2, a first-second electrode EL1_2, a second-second electrode EL2_2, a third-second electrode EL3_2, and a fourth-second electrode EL4_2, a first passivation layer PAS1 (or a first insulating layer), the second and third light-emitting elements LD2 and LD3, a second passivation layer PAS2 (or a second insulating layer), some or a number of intermediate electrodes, for example, a first-second intermediate electrode CTE1_2 and a third-first intermediate electrode CTE3_1, a third passivation layer PAS3 (or a third insulating layer), and other intermediate electrodes, for example, a second-first intermediate electrode CTE2_1 and a second-second intermediate electrode CTE2_2, which may be sequentially disposed or formed on the protective layer PSV (or the pixel circuit layer PCL).

The first-second bank pattern BNKP1_2, the second bank pattern BNKP2, and the third-second bank pattern BNKP3_2 may be disposed on the protective layer PSV. The first-second bank pattern BNKP1_2, the second bank pattern BNKP2, and the third-second bank pattern BNKP3_2 may be disposed in the second emission area EMA2 (see FIG. 5) to be spaced apart from each other. The first-second bank pattern BNKP1_2, the second bank pattern BNKP2, and the third-second bank pattern BNKP3_2 may protrude on the pixel circuit layer PCL in a third direction DR3. According to embodiments, the first-second bank pattern BNKP1_2, the second bank pattern BNKP2, and the third-second bank pattern BNKP3_2 may have substantially a same height, but the disclosure is not limited thereto.

According to embodiments, the first-second bank pattern BNKP1_2 may be disposed between the protective layer PSV and the first-second electrode EL1_2. The first-second bank pattern BNKP1_2 may be disposed adjacent to a first end portion EP1 of the second light-emitting element LD2. As an example, a side surface of the first-second bank pattern BNKP1_2 may be positioned adjacent to the first end portion EP1 of the second light-emitting element LD2 and face the first end portion EP1 of the second light-emitting element LD2.

According to embodiments, the second bank pattern BNKP2 may be disposed between the protective layer PSV and the second-second and third-second electrodes EL2_2 and EL3_2. The second bank pattern BNKP2 may be disposed adjacent to a second end portion EP2 of the second light-emitting element LD2. As an example, a side surface of the second bank pattern BNKP2 may be positioned adjacent to the second end portion EP2 of the second light-emitting element LD2 and face the second end portion EP2 of the second light-emitting element LD2. The second bank pattern BNKP2 may also be disposed adjacent to a second end portion EP2 of a third light-emitting element LD3. As an example, another side surface of the second bank pattern BNKP2 may be positioned adjacent to the second end portion EP2 of the third light-emitting element LD3 and face the second end portion EP2 of the third light-emitting element LD3.

According to embodiments, the third-second bank pattern BNKP3_2 may be disposed between the protective layer PSV and the fourth-second electrode EL4_2. The third-second bank pattern BNKP3_2 may be disposed adjacent to a first end portion EP1 of the third light-emitting element LD3. As an example, a side surface of the third-second bank pattern BNKP3_2 may be positioned adjacent to the first end portion EP1 of the third light-emitting element LD3 and face the first end portion EP1 of the third light-emitting element LD3.

According to embodiments, the first-second bank pattern BNKP1_2, the second bank pattern BNKP2, and the third-second bank pattern BNKP3_2 may have various shapes. As an example, as shown in FIG. 16A, the first-second bank pattern BNKP1_2, the second bank pattern BNKP2, and the third-second bank pattern BNKP3_2 may have a substantially trapezoidal cross-sectional shape of which a width is gradually decreased upward. At least one side surface or a side surface of each of the first-second bank pattern BNKP1_2, the second bank pattern BNKP2, and the third-second bank pattern BNKP3_2 may be an inclined surface. As another example, the first-second bank pattern BNKP1_2, the second bank pattern BNKP2, and the third-second bank pattern BNKP3_2 may have a substantially semicircular or substantially semi-elliptical cross section of which a width is gradually decreased upward. At least one or a side surface of each of the first-second bank pattern BNKP1_2, the second bank pattern BNKP2, and the third-second bank pattern BNKP3_2 may be a curved surface. For example, the shapes of the first-second bank pattern BNKP1_2, the second bank pattern BNKP2, and the third-second bank pattern BNKP3_2 are not limited to particular shapes and may be variously changed. According to embodiments, at least one of the first-second bank pattern BNKP1_2, the second bank pattern BNKP2, and the third-second bank pattern BNKP3_2 may be omitted, or the position thereof may be changed.

The first-second bank pattern BNKP1_2, the second bank pattern BNKP2, and the third-second bank pattern BNKP3_2 may include an insulating material including an inorganic and/or organic material. As an example, the first-second bank pattern BNKP1_2, the second bank pattern BNKP2, and the third-second bank pattern BNKP3_2 may include at least one inorganic film including various inorganic insulating materials such as silicon nitride (SiNₓ) and silicon oxide (SiOₓ). As another example, the first-second bank pattern BNKP1_2, the second bank pattern BNKP2, and the third-second bank pattern BNKP3_2 may include at least one organic film and/or at least one photoresist film including various inorganic insulating materials or may be formed as an insulator formed as a single layer or multiple layers including organic and/or inorganic materials in combination. For example, the materials of the first-second bank pattern BNKP1_2, the second bank pattern BNKP2, and the third-second bank pattern BNKP3_2 may be variously changed.

In an embodiment, the first-second bank pattern BNKP1_2, the second bank pattern BNKP2, and the third-second bank pattern BNKP3_2 may function as reflective members. As an example, the first-second bank pattern BNKP1_2, the second bank pattern BNKP2, and the third-second bank pattern BNKP3_2 may function as the reflective members which guide light, emitted by each of light-emitting elements LD, in a desired direction to improve the luminous efficiency of the pixel PXL, together with the first-second electrode EL1_2, the second-second electrode EL2_2, the third-second electrode EL3_2, and the fourth-second electrode EL4_2 provided thereon.

The first-second electrode EL1_2, the second-second electrode EL2_2, the third-second electrode EL3_2, and the fourth-second electrode EL4_2 may be disposed on the first-second bank pattern BNKP1_2, the second bank pattern BNKP2, and the third-second bank pattern BNKP3_2. The first-second electrode EL1_2, the second-second electrode EL2_2, the third-second electrode EL3_2, and the fourth-second electrode EL4_2 may be spaced apart from each other in the second emission area EMA2.

According to embodiments, the first-second electrode EL1_2, the second-second electrode EL2_2, the third-second electrode EL3_2, and the fourth-second electrode EL4_2 disposed on the first-second bank pattern BNKP1_2, the second bank pattern BNKP2, and the third-second bank pattern BNKP3_2 may have shapes corresponding to those of the first-second bank pattern BNKP1_2, the second bank pattern BNKP2, and the third-second bank pattern BNKP3_2. For example, the first-second electrode EL1_2, the second-second electrode EL2_2, the third-second electrode EL3_2, and the fourth-second electrode EL4_2 may have inclined or curved surfaces corresponding to the first-second bank pattern BNKP1_2, the second bank pattern BNKP2, and the third-second bank pattern BNKP3_2 and may protrude in the third direction DR3.

Each of the first-second electrode EL1_2, the second-second electrode EL2_2, the third-second electrode EL3_2, and the fourth-second electrode EL4_2 may be made of a material having a reflectance in order to allow light, emitted by each of the light-emitting elements LD, to travel in an image display direction (or a front direction) of the display device. Each of the first-second electrode EL1_2, the second-second electrode EL2_2, the third-second electrode EL3_2, and the fourth-second electrode EL4_2 may be made of a conductive material (or substance) having a reflectance. The conductive material (or substance) may include an opaque metal that is advantageous in reflecting light, emitted by the light-emitting elements LD in the image display direction of the display device. The opaque metal may include, for example, a metal such as silver (Ag), magnesium (Mg), aluminum (Al), platinum (Pt), palladium (Pd), gold (Au), nickel (N1), neodymium (Nd), iridium (Ir), chromium (Cr), titanium (Ti), or an alloy thereof. According to embodiments, each of the first-second electrode EL1_2, the second-second electrode EL2_2, the third-second electrode EL3_2, and the fourth-second electrode EL4_2 may include a transparent conductive material (or substance). The transparent conductive material may include a conductive oxide such as indium tin oxide (ITO), indium zinc oxide (IZO), zinc oxide (ZnO), indium gallium zinc oxide (IGZO), or indium tin zinc oxide (ITZO), or a conductive polymer such as poly(3,4-ethylenedioxythiophene) (PEDOT). In case that each of the first-second electrode EL1_2, the second-second electrode EL2_2, the third-second electrode EL3_2, and the fourth-second electrode EL4_2 may include a transparent conductive material, a separate conductive layer made of an opaque metal may be included to reflect light, emitted by the light-emitting elements LD, in the image display direction of the display device. However, the respective materials of the first-second electrode EL1_2, the second-second electrode EL2_2, the third-second electrode EL3_2, and the fourth-second electrode EL4_2 are not limited to the above-described materials.

Further, each of the first-second electrode EL1_2, the second-second electrode EL2_2, the third-second electrode EL3_2, and the fourth-second electrode EL4_2 may be formed as a single layer or multiple layers. As an example, each of the first-second electrode EL1_2, the second-second electrode EL2_2, the third-second electrode EL3_2, and the fourth-second electrode EL4_2 may include at least one reflective electrode layer. Each of the first-second electrode EL1_2, the second-second electrode EL2_2, the third-second electrode EL3_2, and the fourth-second electrode EL4_2 may further include at least one transparent electrode layer disposed above and/or below the reflective electrode layer and/or at least one conductive capping layer covering or overlapping upper portions of the reflective electrode layer and/or the transparent electrode layer.

According to embodiments, the reflective electrode layer of each of the first-second electrode EL1_2, the second-second electrode EL2_2, the third-second electrode EL3_2, and the fourth-second electrode EL4_2 may be made of a conductive material having a uniform reflectance. As an example, the reflective electrode layer may include an opaque metal, but the disclosure is not limited thereto. For example, the reflective electrode layer may be made of various reflective conductive materials. In case that each of the first-second electrode EL1_2, the second-second electrode EL2_2, the third-second electrode EL3_2, and the fourth-second electrode EL4_2 may include the reflective electrode layer, the reflective electrode layer may allow light, which is emitted from both end portions, for example, the first and second end portions EP1 and EP2, of each of the second and third light-emitting elements LD2 and LD3, to further travel in the third direction DR3 (for example, a direction in which an image is displayed). For example, in case that the first-second electrode EL1_2, the second-second electrode EL2_2, the third-second electrode EL3_2, and the fourth-second electrode EL4_2 have the substantially inclined or substantially curved surfaces corresponding to the shapes of the first-second bank pattern BNKP1_2, the second bank pattern BNKP2, and the third-second bank pattern BNKP3_2 and face the first and second end portions EP1 and EP2 of the second and third light-emitting elements LD2 and LD3, light emitted from the first and second end portions EP1 and EP2 of each of the second and third light-emitting element LD2 and LD3 may further travel in the third direction DR3 by being reflected by the first-second electrode EL1_2, the second-second electrode EL2_2, the third-second electrode EL3_2, and the fourth-second electrode EL4_2. Therefore, the efficiency of light emitted by the second and third light-emitting elements LD2 and LD3 may be improved.

The transparent electrode layer of each of the first-second electrode EL1_2, the second-second electrode EL2_2, the third-second electrode EL3_2, and the fourth-second electrode EL4_2 may include various transparent conductive materials. In an embodiment, each of the first-second electrode EL1_2, the second-second electrode EL2_2, the third-second electrode EL3_2, and the fourth-second electrode EL4_2 may be formed as a triple layer having a stacked structure of ITO/Ag/ITO. As described above, in case that the first-second electrode EL1_2, the second-second electrode EL2_2, the third-second electrode EL3_2, and the fourth-second electrode EL4_2 are formed as at least two or more multiple layers, a voltage drop due to a signal delay (RC delay) may be minimized. Therefore, it is possible to effectively transmit a desired voltage to the second and third light-emitting elements LD2 and LD3.

In case that each of the first-second electrode EL1_2, the second-second electrode EL2_2, the third-second electrode EL3_2, and the fourth-second electrode EL4_2 may include the conductive capping layer covering or overlapping the reflective electrode layer and/or the transparent electrode layer, it is possible to prevent damage to the reflective electrode layers of the first-second electrode EL1_2, the second-second electrode EL2_2, the third-second electrode EL3_2, and the fourth-second electrode EL4_2 in a process of manufacturing the pixel PXL. However, the conductive capping layer may be optionally included in the first-second electrode EL1_2, the second-second electrode EL2_2, the third-second electrode EL3_2, and the fourth-second electrode EL4_2 and may be omitted according to embodiments. The conductive capping layer may be regarded as a component of each of the first-second electrode EL1_2, the second-second electrode EL2_2, the third-second electrode EL3_2, and the fourth-second electrode EL4_2 or may be regarded as a separate component disposed on the first-second electrode EL1_2, the second-second electrode EL2_2, the third-second electrode EL3_2, and the fourth-second electrode EL4_2.

In an embodiment, the markings VP described with reference to FIGS. 7 to 15 may be formed in areas, of the first-second electrode EL1_2, the second-second electrode EL2_2, the third-second electrode EL3_2, and the fourth-second electrode EL4_2, overlapping the first-second bank pattern BNKP1_2, the second bank pattern BNKP2, and the third-second bank pattern BNKP3_2. For example, as shown in FIG. 16A, the markings VP may be formed in an area, of the first-second electrode EL1_2, overlapping an upper surface of the first-second bank pattern BNKP1_2.

In an embodiment, the markings VP described with reference to FIGS. 7 to 15 may be formed in areas, of the first-second electrode EL1_2, the second-second electrode EL2_2, the third-second electrode EL3_2, and the fourth-second electrode EL4_2, not overlapping the first-second bank pattern BNKP1_2, the second bank pattern BNKP2, and the third-second bank pattern BNKP3_2. For example, as shown in FIG. 16B, the markings VP may be formed in an area, of the first-second electrode EL1_2, contacting or directly contacting the protective layer PSV. For example, the markings VP may contact or directly contact the protective layer PSV and may be formed in an area, of the first-second electrode EL1_2, adjacent to a bank BNK.

FIGS. 16A and 16B illustrate that the markings VP are the concave patterns described with reference to FIG. 8A, but the disclosure is not limited thereto, and as described with reference to FIG. 8B, the markings VP may be holes (or openings) passing through a corresponding electrode.

The first passivation layer PAS1 may be disposed on areas of the first-second electrode EL1_2, the second-second electrode EL2_2, the third-second electrode EL3_2, and the fourth-second electrode EL4_2. For example, the first passivation layer PAS1 may cover or overlap areas of the first-second electrode EL1_2, the second-second electrode EL2_2, the third-second electrode EL3_2, and the fourth-second electrode EL4_2 and may include openings exposing other areas of the first-second electrode EL1_2, the second-second electrode EL2_2, the third-second electrode EL3_2, and the fourth-second electrode EL4_2.

In an embodiment, the first passivation layer PAS1 may primarily and entirely cover or overlap the first-second electrode EL1_2, the second-second electrode EL2_2, the third-second electrode EL3_2, and the fourth-second electrode EL4_2. After the second and third light-emitting elements LD2 and LD3 are supplied and aligned on the first passivation layer PAS1, the first passivation layer PAS1 may be partially opened to expose the first-second electrode EL1_2, the second-second electrode EL2_2, the third-second electrode EL3_2, and the fourth-second electrode EL4_2 at contact portions, as shown in FIGS. 16A and 16B. As another example, after the supply and alignment of the second and third light-emitting elements LD2 and LD3 are completed, the first passivation layer PAS1 may be patterned in the form of individual patterns that are locally disposed under or below the second and third light-emitting elements LD2 and LD3.

For example, the first passivation layer PAS1 may be interposed between the first-second and second-second electrodes EL1_2 and EL2_2 and the second light-emitting element LD2 and between the third-second and fourth-second electrodes EL3_2 and EL4_2 and the third light-emitting element LD3 and may expose at least one area or an area of each of the first-second electrode EL1_2, the second-second electrode EL2_2, the third-second electrode EL3_2, and the fourth-second electrode EL4_2. The first passivation layer PAS1 may cover or overlap the first-second electrode EL1_2, the second-second electrode EL2_2, the third-second electrode EL3_2, and the fourth-second electrode EL4_2 after the first-second electrode EL1_2, the second-second electrode EL2_2, the third-second electrode EL3_2, and the fourth-second electrode EL4_2 are formed, and may prevent damage to the first-second electrode EL1_2, the second-second electrode EL2_2, the third-second electrode EL3_2, and the fourth-second electrode EL4_2 or precipitation of a metal in a subsequent process. The first passivation layer PAS1 may stably support the second and third light-emitting elements LD2 and LD3. According to embodiments, the first passivation layer PAS1 may be omitted.

According to embodiments, the bank BNK may be disposed or formed on the first passivation layer PAS1.

The second and third light-emitting elements LD2 and LD3 may be supplied and aligned in the second emission area EMA2 in which the first passivation layer PAS1 is formed. As an example, the second and third light-emitting elements LD2 and LD3 may be supplied to the second emission area EMA2 by an inkjet method or the like, and the second and third light-emitting elements LD2 and LD3 may be aligned between the first-second electrode EL1_2 and the second-second electrode EL2_2 and between the third-second electrode EL3_2 and the fourth-second electrode EL4_2 by an alignment voltage (or an alignment signal) applied to the first-second electrode EL1-2, the second-second electrode EL2_2, the third-second electrode EL3_2, and the fourth-second electrode EL4_2.

The second passivation layer PAS2 may be disposed on the second and third light-emitting elements LD2 and LD3, for example, on each of the second light-emitting element LD2 aligned between the first-second and second-second electrodes EL1_2 and EL2_2 and the third light-emitting element LD3 aligned between the third-second electrode EL3_2 and the fourth-second electrode EL4_2 and may expose the first and second end portions EP1 and EP2 of each of the second and third light-emitting elements LD2 and LD3. For example, the second passivation layer PAS2 may not cover or overlap the first and second end portions EP1 and EP2 of each of the second and third light-emitting elements LD2 and LD3 and may be partially disposed only on an area of each of the second and third light-emitting elements LD2 and LD3. The second passivation layer PAS2 may be formed in an independent pattern, but the disclosure is not limited thereto. In case that a space is present between the first passivation layer PAS1 and the second and third light-emitting elements LD2 and LD3 before the second passivation layer PAS2 is formed, the space may be filled with the second passivation layer PAS2. Therefore, the light-emitting elements LD may be supported more stably.

A first-second intermediate electrode CTE1_2 may be disposed on the first-second electrode EL1_2 and on the first end portion EP1 of the second light-emitting element LD2. The first-second intermediate electrode CTE1_2 may electrically connect the first-second electrode EL1_2 and the first end portion EP1 of the second light-emitting element LD2.

The first-second intermediate electrode CTE1_2 may be disposed on an area of the first-second electrode EL1_2 not covered or overlapped by the first passivation layer PAS1 to contact the first-second electrode EL1_2. A first-second intermediate electrode CTE1_2 may also be disposed on the first end portion EP1 of the second light-emitting element LD2 so as to contact the first end portion EP1 of the second light-emitting element LD2 adjacent to the first-second electrode EL1_2. For example, the first-second intermediate electrode CTE1_2 may cover or overlap the first end portion EP1 of the second light-emitting element LD2 and at least one area or an area, of the first-second second electrode EL1_2, corresponding to the first end portion EP1.

Likewise, a third-first intermediate electrode CTE3_1 may be disposed on the third-second electrode EL3_2 and the second end portion EP2 of the third light-emitting element LD3. The third-first intermediate electrode CTE3_1 may electrically connect the third-second electrode EL3_2 and the second end portion EP2 of the third light-emitting element LD3.

The third-first intermediate electrode CTE3_1 may be disposed on an area of the third-second electrode EL3_2 not covered or overlapped by the first passivation layer PAS1 to contact the third-second electrode EL3_2. The third-first intermediate electrode CTE3_1 may be disposed on the second end portion EP2 of the third light-emitting element LD3 so as to contact the second end portion EP2, of the third light-emitting element LD3, adjacent to the third-second electrode EL3_2. For example, the third-first intermediate electrode CTE3_1 may cover or overlap the second end portion EP2 of the third light-emitting element LD3 and at least one area or an area, of the third-second electrode EL3_2, corresponding to the second end portion EP2.

As shown in FIGS. 16A and 16B, the first-second intermediate electrode CTE1_2 and the third-first intermediate electrode CTE3_1 may be disposed in a same layer. The first-second intermediate electrode CTE1_2 and the third-first intermediate electrode CTE3_1 may be formed using a same conductive material by a same process, but the disclosure is not limited thereto.

The third passivation layer PAS3 may be disposed on the first-second intermediate electrode CTE1_2 and the third-first intermediate electrode CTE3_1. The third passivation layer PAS3 may cover or overlap the first-second intermediate electrode CTE1_2 and the third-first intermediate electrode CTE3_1.

A second-first intermediate electrode CTE2_1 may be disposed on the second-second electrode EL2_2 and the second end portion EP2 of the second light-emitting element LD2. The second-first intermediate electrode CTE2_1 may electrically connect the second-second electrode EL2_2 and the second end portion EP2 of the second light-emitting element LD2.

The second-first intermediate electrode CTE2_1 may be disposed on an area of the second-second electrode EL2_2 not covered or overlap by the second passivation layer PAS2 to contact the second-second electrode EL2_2. The second-first intermediate electrode CTE2_1 may also be disposed on the second end portion EP2 of the second-light-emitting element LD2 so as to contact the second end portion EP2, of the second-light-emitting element LD2, adjacent to the second-second electrode EL2_2. For example, the second-first intermediate electrode CTE2_1 may cover or overlap the second end portion EP2 of the second light-emitting element LD2 and an area, of the second-second electrode EL2_2, corresponding to the second end portion EP2.

Likewise, a second-second intermediate electrode CTE2_2 may be disposed on the fourth-second electrode EL4_2 and the first end portion EP1 of the third light-emitting element LD3. The second-second intermediate electrode CTE2_2 may electrically connect the fourth-second electrode EL4_2 and the first end portion EP1 of the third light-emitting element LD3.

The second-second intermediate electrode CTE2_2 may be disposed on an area of the fourth-second electrode EL4_2 not covered or overlapped by the second passivation layer PAS2 to contact the fourth-second electrode EL42. The second-second intermediate electrode CTE2_2 may also be disposed on the first end portion EP1 of the third-light-emitting element LD3 so as to contact the first end portion EP1, of the third-light-emitting element LD3, adjacent to the fourth-second electrode EL4_2. For example, the second-second intermediate electrode CTE2_2 may cover or overlap the first end portion EP1 of the third light-emitting element LD3 and at least one area or an area, of the fourth-second electrode EL4_2, corresponding to the first end portion EP1.

The second-first intermediate electrode CTE2_1 and the second-second intermediate electrode CTE2_2 constitute a second intermediate electrode CTE2 (see FIG. 5) and thus may be disposed in a same layer as shown in FIGS. 16A and 16B.

FIGS. 16A and 16B illustrate that the first-second intermediate electrode CTE1_2, the second-first intermediate electrode CTE2_1, the third-first intermediate electrode CTE3_1, and the second-second intermediate electrode CTE2_2 contact the first-second electrode EL1_2, the second-second electrode EL2_2, the third-second electrode EL3_2, and the fourth-second electrode EL4_2, respectively, but the disclosure not limited thereto. For example, the first-second intermediate electrode CTE1_2, the second-first intermediate electrode CTE2_1, the third-first intermediate electrode CTE3_1, and the second-second intermediate electrode CTE2_2 may be separated or insulated from the first-second electrode EL1_2, the second-second electrode EL2_2, the third-second electrode EL3_2, and the fourth-second electrode EL4_2 through an insulating layer such as the first passivation layer PAS1 or the second passivation layer PAS2. The first-second intermediate electrode CTE1_2, the second-first intermediate electrode CTE2_1, the third-first intermediate electrode CTE3_1, and the second-second intermediate electrode CTE2_2 may be electrically connected only to the second and third light-emitting elements LD2 and LD3.

According to embodiments, each of the first to third passivation layers PAS1 to PAS3 may be formed as a single layer or multiple layers and may include at least one inorganic and/or organic insulating material. For example, each of the first to third passivation layers PAS1 to PAS3 may include various types of organic or inorganic insulating materials such as silicon nitride (SiNₓ). The material of each of the first to third passivation layers PAS1 to PAS3 is not limited to a particular material. The first to third passivation layers PAS1 to PAS3 may include different insulating materials, or at least some or a number of the first to third passivation layers PAS1 to PAS3 may include a same insulating material.

According to embodiments, an overcoat layer (for example, a layer for planarizing an upper surface of the display element layer DPL) may be entirely formed or disposed on the substrate SUB to cover or overlap the first-second intermediate electrode CTE1_2, the second-first intermediate electrode CTE2_1, the third-first intermediate electrode CTE3_1, and the second-second intermediate electrode CTE2_2, the third passivation layer PAS3, and the bank BNK.

FIGS. 16A and 16B illustrate that some or a number of the first-second intermediate electrode CTE1_2, the second-first intermediate electrode CTE2_1, the third-first intermediate electrode CTE3_1, and the second-second intermediate electrode CTE2_2 are disposed in different layers, but the disclosure is not limited thereto. In an embodiment, the first-second intermediate electrode CTE1_2, the second-first intermediate electrode CTE2_1, the third-first intermediate electrode CTE3_1, and the second-second intermediate electrode CTE2_2 may be disposed in a same layer.

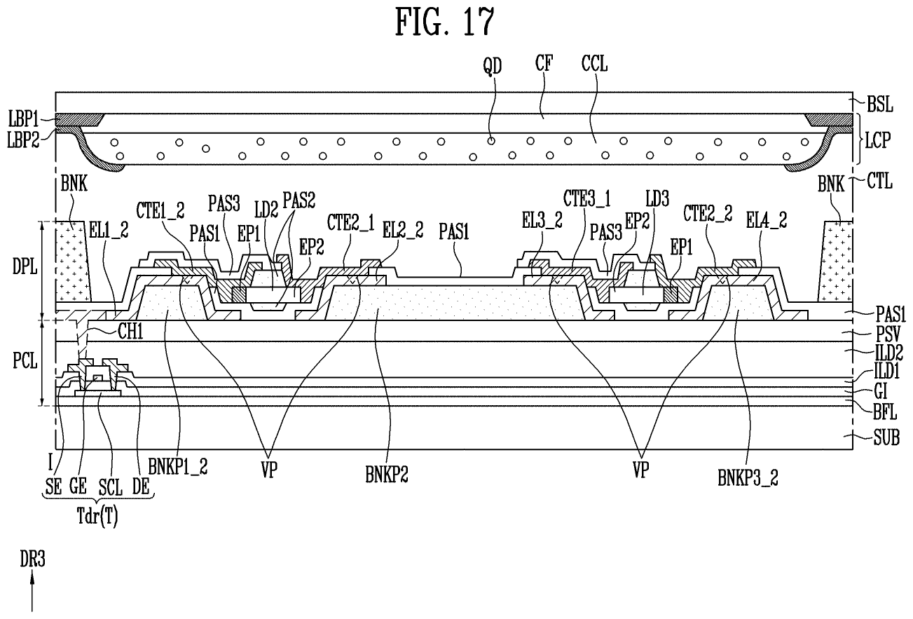

FIG. 17 is a schematic cross-sectional view taken along line I-I′ of FIG. 6 which illustrates a pixel according to an embodiment.

Referring to FIGS. 3, 5, 6, 16A, 16B, and 17, an upper substrate may be further disposed on a display element layer DPL.

The upper substrate may be disposed on the display element layer DPL to cover or overlap a display area DA in which pixels PXL are disposed. Such an upper substrate may constitute an encapsulation substrate (or a thin-film encapsulation layer) and/or a window member of a display device DD. An intermediate layer CTL may be provided or disposed between the upper substrate and the display element layer DPL. The intermediate layer CTL may be a transparent adhesive layer (or a transparent adhesive layer) for enhancing an adhesive force between the display element layer DPL and the upper substrate, for example, an optically clear adhesive layer, but the disclosure is limited thereto.

The upper substrate may include a base layer BSL and a light conversion pattern layer LCP.

The base layer BSL may be a rigid or flexible substrate and the material or physical properties thereof are not limited to a particular material or particular physical properties. The base layer BSL and the substrate SUB may be made of a same material or similar material, or the base layer BSL may be made of a material different from that of the substrate SUB.

The light conversion pattern layer LCP may be disposed on a surface of the base layer BSL to face the pixels PXL of the substrate SUB. The light conversion pattern layer LCP may include a color conversion layer CCL and a color filter CF which correspond to a color.

The color conversion layer CCL may include color conversion particles QD corresponding to a specific or predetermined color. The color filter CF may selectively transmit light having a specific or predetermined color. A color conversion layer CCL may be disposed on the surface of the base layer BSL so as to face a pixel PXL (or a subpixel) and may include the color conversion particles QD that convert light, having a color and emitted by light-emitting elements LD disposed in a pixel PXL, into light having a specific or predetermined color. As an example, in case that a pixel PXL is a red pixel, the color conversion layer CCL may include the color conversion particles QD of red quantum dots that convert light, emitted by the light-emitting elements LD, into red light. As another example, in case that a pixel PXL is a green pixel, the color conversion layer CCL may include the color conversion particles QD of green quantum dots that convert light, emitted by the light-emitting elements LD, into green light. As another example, in case that a pixel PXL is a blue pixel, the color conversion layer CCL may include the color conversion particles QD of blue quantum dots that convert light, emitted by the light-emitting elements LD, into blue light.

The color filter CF may be disposed between the color conversion layer CCL and the base layer BSL and may include a color filter material that selectively transmits light, having a specific or predetermined color, converted by the color conversion layer CCL. The color filter CF may include a red color filter, a green color filter, and a blue color filter.

A first light blocking pattern LBP1 may be disposed between the color filter CF corresponding to a pixel PXL and a color filter (not shown) corresponding to another pixel PXL adjacent to the pixel PXL. The first light blocking pattern LBP1 may be provided or disposed on the base layer BSL so as to overlap a bank BNK provided or disposed in a pixel area PXA of the pixel PXL. According to embodiments, the second light blocking pattern LBP2 may be disposed on the first light blocking pattern LBP1. The first light blocking pattern LBP1 and the second light blocking pattern LBP2 may include a same material or similar material. For example, the first light blocking pattern LBP1 and the second light blocking pattern LBP2 may be a black matrix.

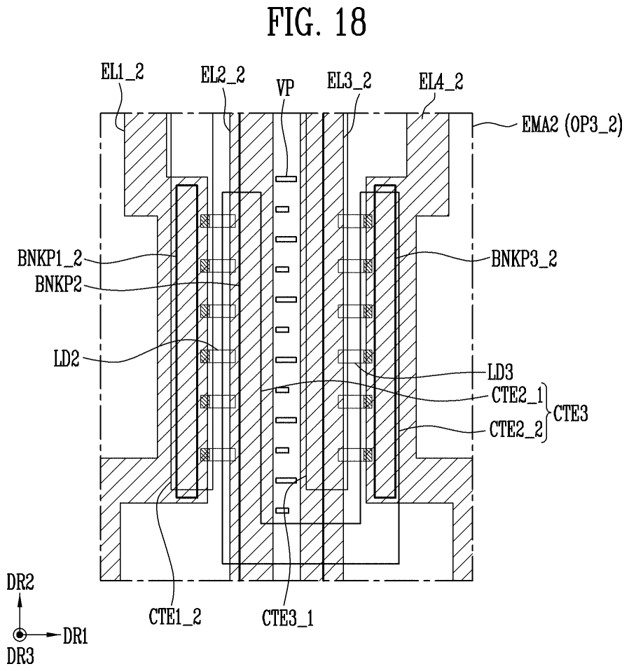

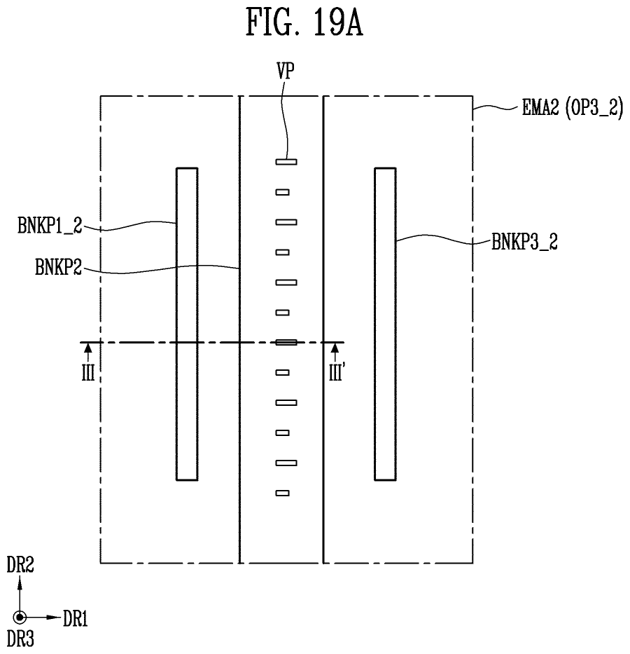

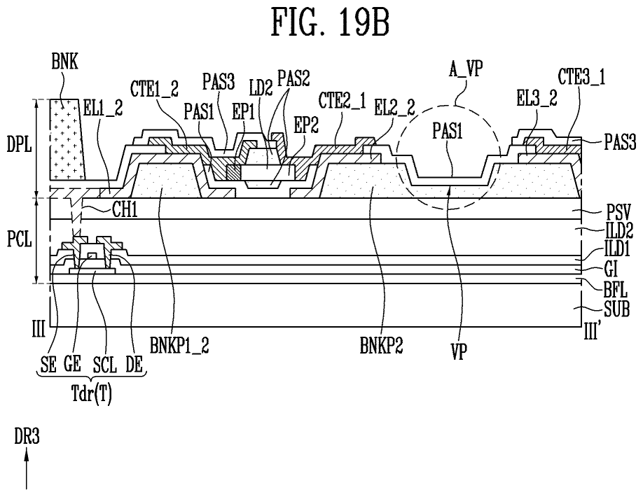

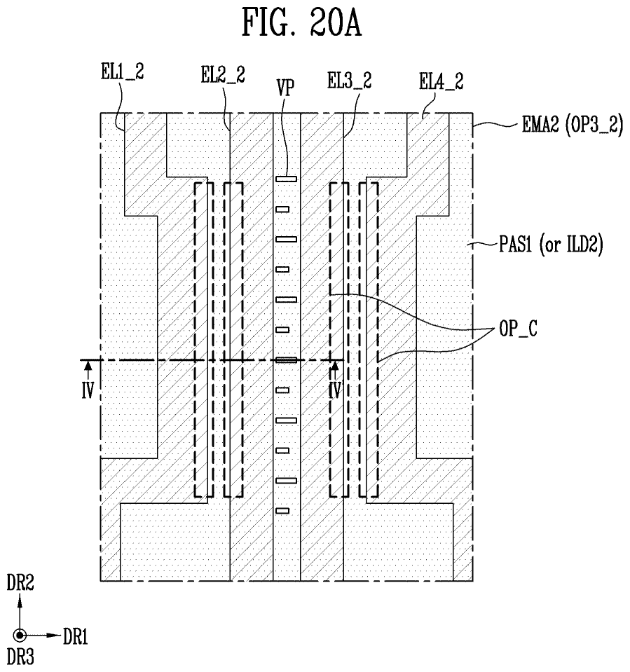

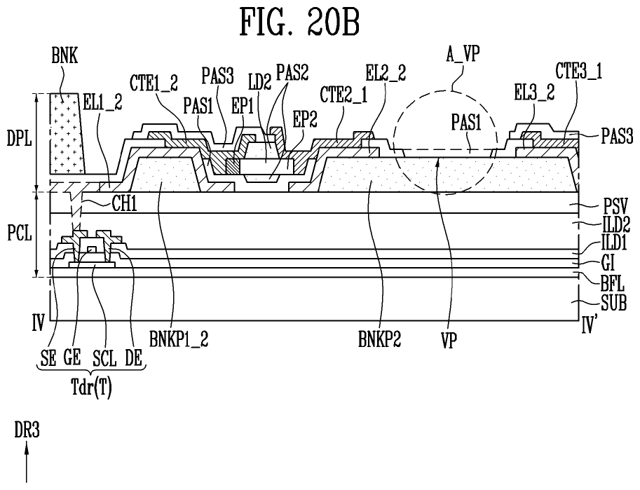

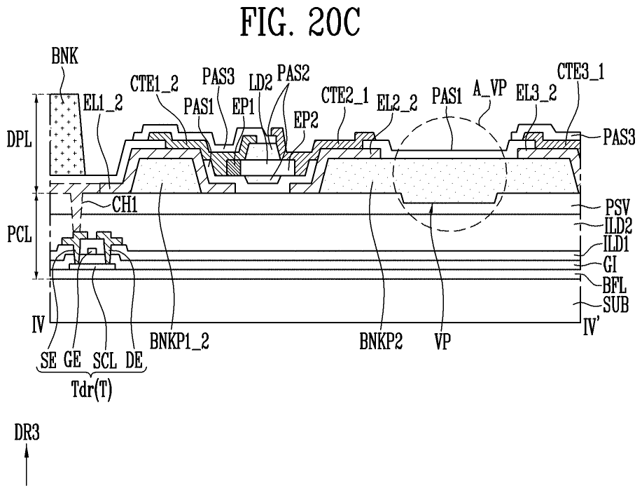

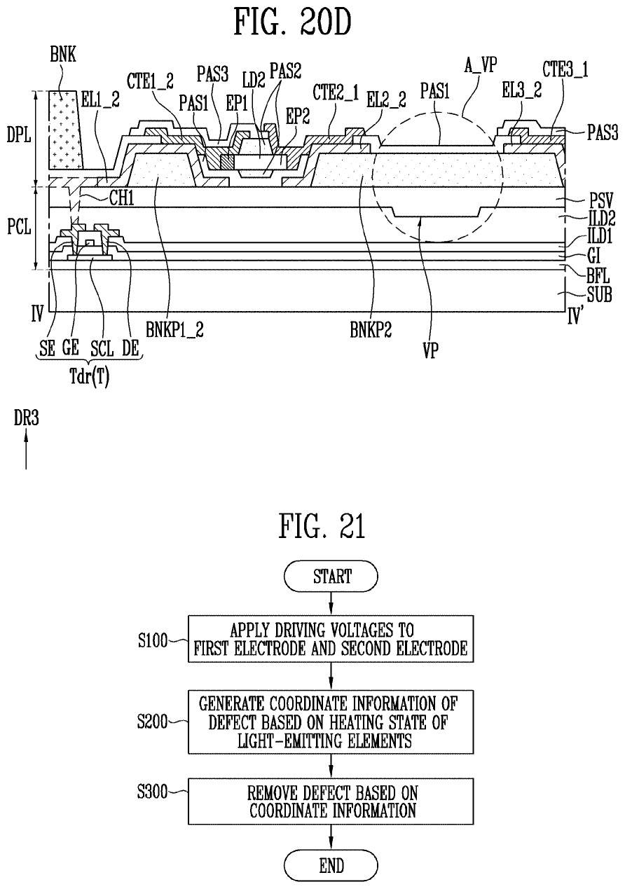

FIG. 18 is a schematic enlarged plan view illustrating the second emission area of FIG. 5 according to an embodiment. FIG. 18 illustrates a schematic view corresponding to FIG. 6. FIG. 19A is a schematic plan view illustrating bank patterns included in the pixel of FIG. 18 according to an embodiment. FIG. 19B is a schematic cross-sectional view taken along line III-III′ of FIG. 19A which illustrates a pixel. FIG. 20A is a schematic plan view illustrating a first passivation layer included in the pixel of FIG. 18 according to an embodiment. FIGS. 20B to 20D are schematic cross-sectional views taken along line IV-IV′ of FIG. 20A which illustrate pixels. FIGS. 19B and 20B to 20D illustrates schematic cross-sectional views corresponding to FIG. 16A.

Referring to FIGS. 3, 5, 6, 18, 16A, 19A, 19B, and 20A to 20D, except for positions at which markings VP are formed, the pixels (or components in a second emission area EMA2) shown in FIGS. 20B to 20D may be substantially identical or similar to the pixels (or components in the second emission area EMA2) shown in FIGS. 6 and 16A. The shape or the like of the markings VP described with reference to FIGS. 7 to 15 may be applied to that or the like of the markings VP. Therefore, repetitive descriptions thereof will be omitted.

The markings VP may be formed on a bank pattern or an insulating layer instead of a first-second electrode EL1_2, a second-second electrode EL2_2, a third-second electrode EL3_2, and a fourth-second electrode EL4_2.

In an embodiment, the markings VP may be formed on at least one of a first-second bank pattern BNKP1_2, a second bank pattern BNKP2, and a third-second bank pattern BNKP3_2. For example, as shown in FIGS. 19A and 19B, the markings VP may be formed on a second bank pattern BNKP2. In other words, in an area A_VP shown in FIG. 19B, the markings VP may be formed on the second bank pattern BNKP2. For example, in a process of forming the second bank pattern BNKP2, a stepped portion may be formed on the second bank pattern BNKP2 by using a mask (for example, a mask including a slit), and thus the markings VP may be formed.

Only a first passivation layer PAS1 is disposed on the second bank pattern BNKP2, and for example, almost no structure is stacked on the second bank pattern BNKP2. Therefore, the markings VP may be visually recognized by an imaging device.

In order for the markings VP to be readily and visually recognized, the markings VP may be formed on the second bank pattern BNKP2 so as to not overlap the first-second electrode EL1_2, the second-second electrode EL2_2, the third-second electrode EL3_2, and the fourth-second electrode EL4_2 in a plan view.

In an embodiment, as shown in FIGS. 20A and 20B, the markings VP may be formed on the first passivation layer PAS1. In other words, in an area A_VP shown in FIG. 20B, the markings VP may be formed on the first passivation layer PAS1. For example, in a process of forming openings OP_C of the first passivation layer PAS1 or the first passivation layer PAS1, a stepped portion or a slit (for example, a slit or hole passing through the first passivation layer PAS1) may be formed using a mask, and thus the markings VP may be formed. Here, the openings OP_C may expose the first-second electrode EL1_2, the second-second electrode EL2_2, the third-second electrode EL3_2, and the fourth-second electrode EL4_2, and a first-second intermediate electrode CTE1_2, a second-first intermediate electrode CTE2_1, a third-first intermediate electrode CTE3_1, and a second-second intermediate electrode CTE2_2 may respectively contact the first-second electrode EL1_2, the second-second electrode EL2_2, the third-second electrode EL3_2, and the fourth-second electrode EL4_2 through the openings OP_C. According to embodiments, the opening OP_C may be omitted.

Since no structure is stacked on the first bank pattern BNKP2, the markings VP may be readily and visually recognized by the imaging device.

In an embodiment, as shown in FIG. 20C, the markings VP may be formed on a protective layer PSV in an area A_VP. For example, in a process of forming a first contact hole CH1 in the protective layer PSV, the markings VP may be formed.

In an embodiment, as shown in FIG. 20C, the markings VP may be formed on a second interlayer insulating layer ILD2 in an area A_VP. For example, in a process of forming first and second terminals DE and SE of a transistor T, a stepped portion or a slit may be formed using a conductive material for forming the first and second terminals DE and SE, and the second interlayer insulating layer ILD2 may be formed on the stepped portion or the slit, and thus the markings VP may be formed.

As described above, the markings VP may be formed on the bank pattern or the insulating layer instead of the first-second electrode EL1_2, the second-second electrode EL2_2, the third-second electrode EL3_2, and the fourth-second electrode EL4_2. For example, in case that the markings VP are formed on the second bank pattern BNKP2 or the first passivation layer PAS1, the markings VP may be more readily and visually recognized by the imaging device, and thus the position of a light-emitting element LD may be more accurately specified or determined.

FIGS. 19B and 20D illustrate that the markings VP are the concave patterns described with reference to FIG. 8A, but the disclosure is not limited thereto, and as described with reference to FIG. 8B, the markings VP may be holes (or openings) passing through a corresponding electrode.

FIGS. 18 to 20D illustrate that the markings VP are formed between the second-second electrode EL2_2 and the third-second electrode EL3_2 (or in the area A_VP shown in 19B, 20B, 20C, and 20D), but the disclosure is not limited thereto. For example, the markings VP may be positioned in a non-emission area NEMA positioned in a first direction DR1 with respect to the pixel PXL shown in FIG. 5.

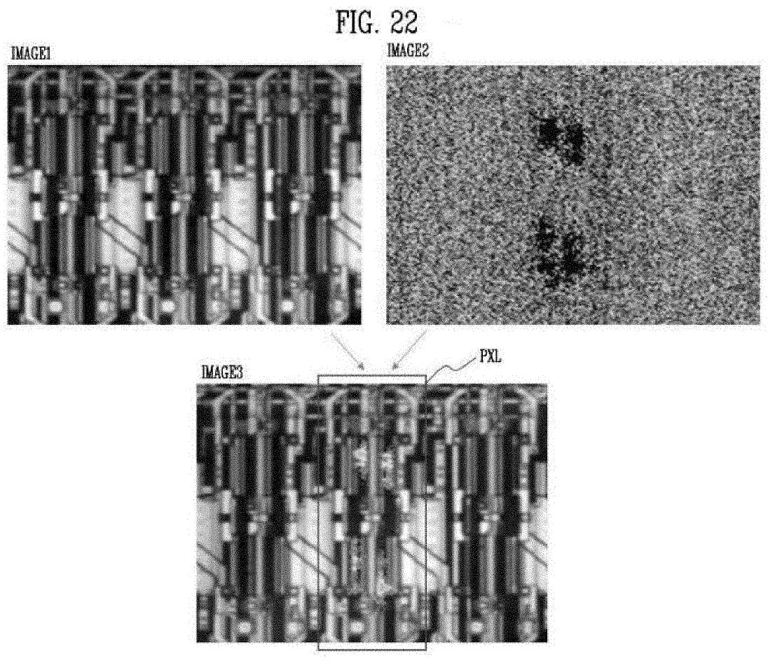

FIG. 21 is a flowchart illustrating a method of repairing a display device according to an embodiment. FIG. 22 illustrates images for describing a process of generating coordinate information of a defect occurring in a display device.

Referring to FIGS. 3, 5, 16A, 16B, 17, 21, and 22, the method of FIG. 21 may be performed on the display device DD of FIG. 3. For example, the method of FIG. 21 may be performed after the third passivation layer PAS3 described with reference to FIGS. 16A and 16B is formed. The method of FIG. 21 may also be performed before the intermediate layer CTL (or the light conversion pattern layer LCP) described with reference to FIG. 17 is formed.

In the method of FIG. 21, driving voltages may be applied to first to fourth electrodes EL1 to EL4 (S100). For example, in the method of FIG. 21, the driving voltages may be applied to the first to fourth electrodes EL1 to EL4 in a manner in which a voltage of a first driving power source VDD is applied to the first power line PL1, a voltage of a second driving power source VSS is applied to a second power line PL2, and a driving voltage is applied to a jth data line Dj, as described with reference to FIG. 4. As another example, in case that the first to fourth electrodes EL1 to EL4 are electrically connected to a power pad portion positioned in a non-display area NDA to receive an alignment signal, the driving voltages may be applied to the first to fourth electrodes EL1 to EL4 through the power pad portion by the method of FIG. 21.

In case that the driving voltages are applied to the first to fourth electrodes EL1 to EL4, a current may flow in light-emitting elements LD, and the light-emitting elements LD may emit heart according to a resistance of the light-emitting elements LD.

In the method of FIG. 21, coordinate information of a defect may be generated based on a heating state of the light-emitting elements LD, and the coordinate information of the defect or a defective light-emitting element LD may be generated based on markings VP (see FIGS. 7 to 15 and 18 to 20D) formed on the first to fourth electrodes EL1 to EL4 or on an insulating layer adjacent to the first to fourth electrodes EL1 to EL4 (S200).

In an embodiment, in the method of FIG. 21, an optical image IMAGE1 of the display device DD (or pixels PXL) may be generated by an imaging device, a heating image IMAGE2 of the light-emitting elements LD may be generated, and a test image IMAGE3 may be generated by mixing or by synthesizing or compositing or combining the optical image IMAGE1 and the heating image IMAGE2. Here, a layout of the pixel PXL and the markings VP may be displayed on the optical image IMAGE1.

As shown in FIG. 22, a temperature of some or a number of areas, of the heating image IMAGE2, corresponding to the defective light-emitting element LD may be different from a temperature of other areas thereof (for example, areas in which defective light-emitting elements LD are disposed). For example, an overcurrent may flow in a light-emitting element LD in which a short circuit has occurred, and the light-emitting element LD may emit relatively great amounts of heat. An area in which a defect has occurred may be displayed on the test image IMAGE3 generated by mixing or compositing or combining the optical image IMAGE1 and the heating image IMAGE2.

Therefore, in the method of FIG. 21, it may be determined that a defect has occurred in an area (or point) of which a temperature value deviates from or is out of a reference range in the test image IMAGE3, and information (for example, position information) about markings VP adjacent to the area in which the defect has occurred may be determined as coordinate information of the defect.

In the method of FIG. 21, the defect may be removed from the display device DD (or the pixel PXL) based on the coordinate information of the defect (S300).

For example, in the method of FIG. 21, the defect may be removed by cutting a portion of a light-emitting element LD or a corresponding electrode corresponding to the coordinate information of the defect by a laser device.

For reference, the generation of the optical image IMAGE1, the heating image IMAGE2, and the test image IMAGE3 (for example, a heating test process) may be performed by an imaging device, and the removal of the defect (for example, a repairing process including a laser cutting process) may be performed using a laser device (or a repair device). For example, the heating test process and the repairing process may be performed separately using different devices. Therefore, the optical image IMAGE1, the heating image IMAGE2, and the test image IMAGE3 (for example, the test image IMAGE3) or the coordinate information of the defect acquired by the heating test process may be provided to the laser device, and the laser device may perform the repairing process based on the optical image IMAGE1, the heating image IMAGE2, and the test image IMAGE3 (for example, the test image IMAGE3) or the coordinate information of the defect.

However, in case that the markings VP are not formed, no reference point may be provided in the repairing process (for example, a reference point for specifying a position at which a defect has occurred), or the reference point in the repairing process may be different from that in the heating test process (or the test image IMAGE3). Therefore, the defect may not be accurately removed.

Therefore, in the method of FIG. 21, the markings VP formed on the first to fourth electrodes EL1 to EL4 or on the insulating layer adjacent to the first to fourth electrodes EL1 to EL4 may be set as a reference point (for example, a reference point for specifying a position of a point at which a defect has occurred), and the point at which the defect has occurred may be accurately specified, and thus the defect may be more accurately removed.

In case that the point at which the defect has occurred is accurately specified using the markings VP in the heating test process, even if the coordinate information of the defect obtained in the heating test process is provided to the laser device in the repairing process, the defect may be accurately removed.

Before the method of FIG. 21 is performed, a test (for example, a lighting test) on the pixel circuit PXC described with reference to FIG. 4 may be first performed. For example, in case that there is no abnormality in the pixel circuit PXC, the method of FIG. 21 may be performed. After the method of FIG. 21 is performed, the intermediate layer CTL (or the light conversion pattern layer LCP) described with reference to FIG. 17 may be formed.

Since a display device according to embodiments may include markings formed on at least one of electrodes or an insulating layer adjacent thereto, positions of defects (for example, short-circuited light-emitting elements) may be accurately specified or determined based on the markings, and thus defects of the display device may be more accurately repaired.

In a method of repairing a display device according to embodiments, a reference point for specifying positions of defects may be set using markings, coordinate information of the defects may be accurately set based on the reference point (for example, the markings), and thus defects of the display device may be more accurately repaired based on only the coordinate information of the defect in a repair process separate from a heat generation test.

The effects according to an embodiment are not limited by the above-described contents, and more various effects are included in the specification.

Although embodiments have been described, it is understood that the disclosure should not be limited to these embodiments but various changes and modifications can be made by one of ordinary skill in the art within the spirit and scope of the disclosure as hereinafter claimed.

Therefore, the technical scope of the disclosure is not limited to the embodiments described herein, but may be determined by the claims.

What is claimed is:

1. A display device comprising:
a first electrode and a second electrode which are disposed on a substrate and face each other;
light-emitting elements disposed between the first electrode and the second electrode; and
markings formed on the first electrode in a first extending direction of the first electrode in a plan view.

2. The display device of claim 1, wherein each of the markings is a substantially concave pattern or a substantially convex pattern on a surface of the first electrode.

3. The display device of claim 1, wherein the markings are spaced apart from each other at a same interval over an entire section corresponding to the light-emitting elements in the first extending direction of the first electrode.

4. The display device of claim 3, wherein the same interval is in a range of about 4 μm to about 10 μm.

5. The display device of claim 1, wherein each of the markings has a substantially circular planar shape or a substantially quadrangular planar shape.

6. The display device of claim 1, wherein
each of the markings is adjacent to a first side of the first electrode in a second extending direction perpendicular to the first extending direction of the first electrode in the plan view, and
the first side of the first electrode faces the second electrode.

7. The display device of claim 1, wherein each of the markings extends in a second extending direction perpendicular to the first extending direction of the first electrode in a plan view.

8. The display device of claim 7, wherein the markings include markings having different lengths in the second extending direction.

9. The display device claim 1, wherein
each of the markings contacts a second side of the first electrode in a second extending direction perpendicular to the first extending direction of the first electrode, and
the second side of the first electrode is opposite to a first side of the first electrode facing the second electrode.

10. The display device of claim 1, wherein the markings are formed in the second electrode in an extending direction of the second electrode.

11. The display device of claim 1, wherein the first electrode and the second electrode are disposed in a same layer.

12. A display device comprising:
an insulating layer disposed on a substrate;
a first bank pattern and a second bank pattern which are disposed on the insulating layer and face each other;
a first electrode disposed on the first bank pattern;
a second electrode disposed on the second bank pattern;
a first passivation layer disposed on the first electrode and the second electrode; and
light-emitting elements disposed on the first passivation layer between the first electrode and the second electrode, wherein
markings are formed in one of the insulating layer, the first bank pattern, the second bank pattern, and the first passivation layer, and
the markings correspond to a section in which the light-emitting elements are disposed in a plan view.

13. The display device of claim 12, wherein the markings are formed in the second bank pattern.

14. The display device of claim 13, wherein the markings are formed in an area of the second bank pattern not overlapping the second electrode in a plan view.

15. The display device of claim 12, wherein the markings are formed in the first passivation layer.

16. The display device of claim 12, further comprising:
a transistor disposed between the substrate and the insulating layer and electrically connected to the first electrode, wherein
the insulating layer contacts a source electrode and a drain electrode of the transistor, and
the markings are formed in the insulating layer.

17. A method of repairing a display device comprising:
applying driving voltages to a first electrode and a second electrode extending to face each other on a substrate;
forming markings on the first electrode or on an insulating layer adjacent to the first electrode;
generating coordinate information of a defect based on a heating state of light-emitting elements disposed between the first electrode and the second electrode;
generating the coordinate information based on the markings; and
removing the defect from the display device based on the coordinate information.

18. The method of claim 17, wherein the generating of the coordinate information includes:
generating an optical image of the display device through an imaging device;
generating a heating image of the light-emitting elements; and
generating a test image by combining the optical image and the heating image,
wherein the markings are displayed on the optical image.

19. The method of claim 18, wherein the generating of the coordinate information further includes:
determining that the defect has occurred at a point at which a temperature value deviates from a reference range in the test image; and
determining information of markings adjacent to the defect as the coordinate information.

20. The method of claim 19, wherein
the removing of the defect includes cutting a portion of a light-emitting element or the first electrode corresponding to the coordinate information through a laser device, and
the coordinate information is provided to the laser device and the test image is not provided to the laser device.
